(19) United States
(12) Patent Application Publication
(10) Pub. No.: US 2013/0218494 A1
(43) Pub. Date: Aug. 22, 2013

(54) Systems for Real-Time Available Transfer Capability Determination of Large Scale Power Systems

(71) Applicants: Bigwood Technology, Inc., (US); Tokyo Electric Power Company, Inc., (US); School of Electrical Engineering and Automation, Tianjin University, (US)

(72) Inventors: Hsiao-Dong Chiang, Ithaca, NY (US); Yasuyuki Tada, Tokyo (JP); Cheng-Shan Wang, Tianjin (CN)

(73) Assignees: Bigwood Technology, Inc., Ithaca, NY (US); School of Electrical Engineering and Automation, Tianjin University, Tianjin (CN); Tokyo Electric Power Company, Inc., Tokyo (JP)

(21) Appl. No.: 13/649,587

(22) Filed: Oct. 11, 2012

Related U.S. Application Data
(60) Provisional application No. 61/545,682, filed on Oct. 11, 2011.

(51) Int. Cl. G01R 21/00

(52) U.S. Cl. CPC G01R 21/006
USPC 702/61

(57) ABSTRACT

A system for accurately determining real-time Available Transfer Capability and the required ancillary service of large-scale interconnected power systems in an open-access transmission environment, subject to static and dynamic security constraints of a list of credible contingencies, including line thermal limits, bus voltage limits, voltage stability (steady-state stability) constraints, and transient stability constraints.

### REFERENCE TO RELATED APPLICATIONS

This application claims one or more inventions which were disclosed in Provisional Application No. 61/545,682, filed Oct. 11, 2011, entitled “Systems for Real-Time Available Transfer Capability Determination of Large Scale Power Systems”. The benefit under 35 USC §119(e) of the United States provisional application is hereby claimed, and the aforementioned application is hereby incorporated herein by reference.

### BACKGROUND OF THE INVENTION

1. Field of the Invention

The invention pertains to the field of electric power distribution. More particularly, the invention pertains to analysis of large-scale interconnected power systems.

2. Description of Related Art

The Federal Energy Regulatory Commission's (FERC) open-access NOPR has created far-reaching changes in the wholesale electric industry in the United States. To enforce the open-access transmission policy, FERC further defined a term “Available Transfer Capacity” (ATC) to inform all energy market participants regarding the maximum power transfer capability of a system. Hence, the development of a real-time method for accurately determine available transfer capability is essential in power systems within the open access environment. One main challenge is to quickly and accurately compute the real-time available transfer capability under varying loading conditions, taking into account the static as well as dynamic security constraints of a large number of contingencies.

The de-regulated electricity market has resulted in rather rapid changes in operating conditions. System operators now face more new, unknown power flow patterns than ever before. At the same time, economic pressure on the electricity market and on grid operators, coupled with limited investment in new generation and transmission networks, push power systems close to their stability limits. The uncertainty and variability brought about by renewable energies may further push power systems ever close to or beyond their stability limits.

Available Transfer Capability (ATC) has been used to guide power system operations for setting transfer limits on transmission corridors and key tie-lines. Currently, ATC is mostly calculated using off-line, worst-case scenarios and it results in very conservative calculations of power transfer limits. This traditional tool of off-line ATC calculation is inadequate. Hence, there is a need to calculate the ATC based on actual operating conditions.

Power transfer capability (PTC) refers to the capacity and ability of a transmission network to allow for the reliable transfer of electric power from an area of supply to an area of need by way of all transmission lines (or paths) between two areas under assumed system conditions. In this invention, the terminologies of power transfer capability (PTC) and the power transfer limit (PTL), i.e. (PTC under a specified control scheme) will be used interchangeably. The assumed (current and near-term) operating conditions include several projected factors such as the expected load demands, near-term real power dispatch, the system configuration, and the scheduled power transfers among the interconnected systems.

The power transfer capabilities proposed by NERC are generally the first contingency incremental transfer capability (FCITC) or first contingency total transfer capability (FCTTC) for predicted peak load conditions. FCITC is the amount of electric power incremental above a normal base power that can be transferred in a reliable manner based on all of the following conditions:
(1) for the existing or planned system configuration, and with normal (pre-contingency) operating procedures in effect, all facility loadings are within normal ratings and all voltages are within normal limits,
(2) the electric system is capable of absorbing the dynamic power swings, and remaining stable following a disturbance that results in the loss of any single electric system element, such as a transmission line, transformer, or generation unit,
(3) after the dynamic power swings subside following a disturbance that results in the loss of any single electric system element as described in (2) above, and after the operation of any automatic operating systems, but before any post-contingency operator-initiated system adjustments are implemented, all transmission facility loadings are within emergency ratings and all voltages are within emergency limits.

Note that condition (1) is related to the static security constraints under the first contingency of the pre-contingency operating conditions while condition (3) is concerned with the static security constraints of the post-contingency operating conditions. Condition (2) is the typical (angle) transient stability constraint and may not include the voltage dip problem during transients as constraints.

A set of interface tie-lines can be defined between a sending area and a receiving area. FIG. 1 illustrates the concept of interface tie-lines.

In FIG. 1 the transmission lines L11, L12, . . . , L1r between the sending area and the receiving area form a set of interface tie-lines. The line (real) power flows, p11, p12, . . . , p1r in the set of interface tie-lines form the interface tie-line flow.

The system-wide PTC can be mapped into an interface tie-line PTC. Depending on the selection of interface tie-lines, the corresponding interface tie-line PTC will be different. FIG. 2 illustrates the interface tie-line dependent PTC. The system-wide PTC can be hard to visualize while the interface dependent PTCs are amenable to visualization.

The Continuation Power Flow Method (or “CPFLOW”) is a method for tracing power system behavior described in a paper “CPFLOW: Tool for Tracing Power System Steady-State Stationary Behavior Due to Load and Generation Variations”, Chiang, Sha and Balu, IEEE Transactions on Power Systems, Vol. 10, No. 2, pages 623-634, May 1995, which is incorporated herein by reference.

A BCU method is a systematic method to find the controlling unstable equilibrium point, as disclosed in U.S. Pat. No. 5,483,462 “On-line method for determining power system transient stability” granted to Dr. Hsiao-Dong Chiang, one of the inventors herein, which is incorporated herein by reference.

A BCU Classifier is a method for ensuring that unstable contingencies are captured and reduced, as described in “Development of BCU Classifiers for On-Line Dynamic Contingency Screening of Electric Power Systems”, Chiang, Wang and Li, IEEE Transactions on Power Systems, Vol. 14, No. 2, pages 660-666, May 1999.

### SUMMARY OF THE INVENTION

The invention describes a system for accurately determining real-time Available Transfer Capability (ATC) and the required ancillary service of large-scale interconnected power systems in an open-access transmission environment, subject to static and dynamic security constraints of a list of credible contingencies, including line thermal limits, bus voltage limits, voltage stability (steady-state stability) constraints, and transient stability constraints.

### BRIEF DESCRIPTION OF THE DRAWING

FIG. 1 shows a diagram of interface tie-lines.

FIG. 2 shows a diagram of an interface tie-line dependent Power Transfer Capability (PTC), mapped from a system-wide PTC

FIG. 3 shows a block diagram of schemes for ranking a list of contingencies in terms of load margin, voltage limit and thermal limit.

FIG. 4 shows a graph of how a stress pattern spans the entire feasible generation/load stress space

FIG. 5 shows diagrams of how a system-wide static PTC nomogram is mapped into each pair of tie-line interfaces static PTC nomogram.

FIG. 6 shows a diagram of a tie-line power flow measured by PMU's placed across the interface while the static PTC is computed.

FIG. 7 shows a diagram of tie-line power flow of interface #i as measured by PMU's placed across interface #i, while the tie-line power flow of interface #j is measured by PMU's placed across interface #j.

FIG. 8 shows a block diagram of an architecture of a PMU-assisted real-time static available transfer capability determination system.

FIG. 9 shows an architecture of a PMU-assisted, load-margin-based, real-time static available transfer capability determination system.

FIG. 10 shows a graphic of base-case interchange power flows in a subsystem composed of 9 areas with 1135 buses and 2216 transmission lines.

FIG. 11 shows a tale of accuracy of a BCU-limiter, as compared with the time-domain approach on 12 contingencies in terms of error.

FIG. 12 shows a diagram of tie-line power flow of an interface measured by PMU's placed across the interface while the dynamic PTC is computed by the method of the invention.

FIG. 13 shows a block diagram of an architecture of a PMU-assisted, real-time dynamic available transfer capability determination system with output displays of one-dimensional meters for each interface.

FIG. 14 shows a block diagram of an architecture of a PMU-assisted, real-time dynamic available transfer capability determination system with output displays via two-dimensional nomograms for each pair interfaces.

FIG. 15 shows a diagram of tie-line power flow in an interface measured by PMU's placed across the interface while the static and dynamic PTC is computed by the method of the invention.

FIG. 16 shows a graph of the output of a PMU-assisted, real-time static and dynamic ATC determination system, expressed as a two-dimensional nomogram.

FIG. 17 shows a block diagram of an architecture of a PMU-assisted, real-time static and dynamic available transfer capability determination system with one-dimensional meter displays for each interface.

FIG. 18 shows a block diagram of an architecture of a PMU-assisted, real-time static and dynamic available transfer capability determination system with two-dimensional monogram displays for each pair interfaces.

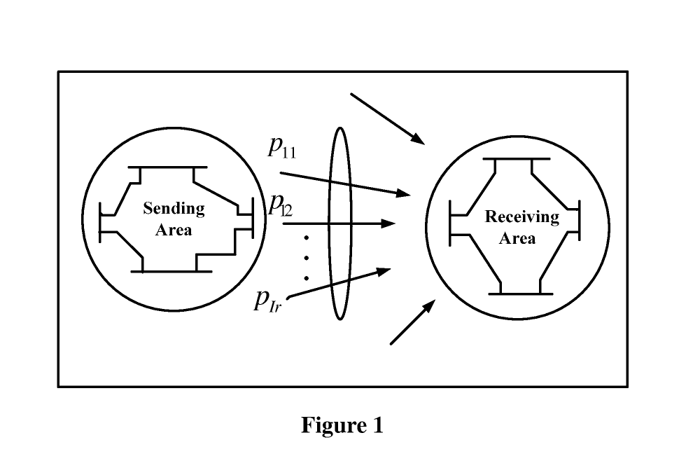

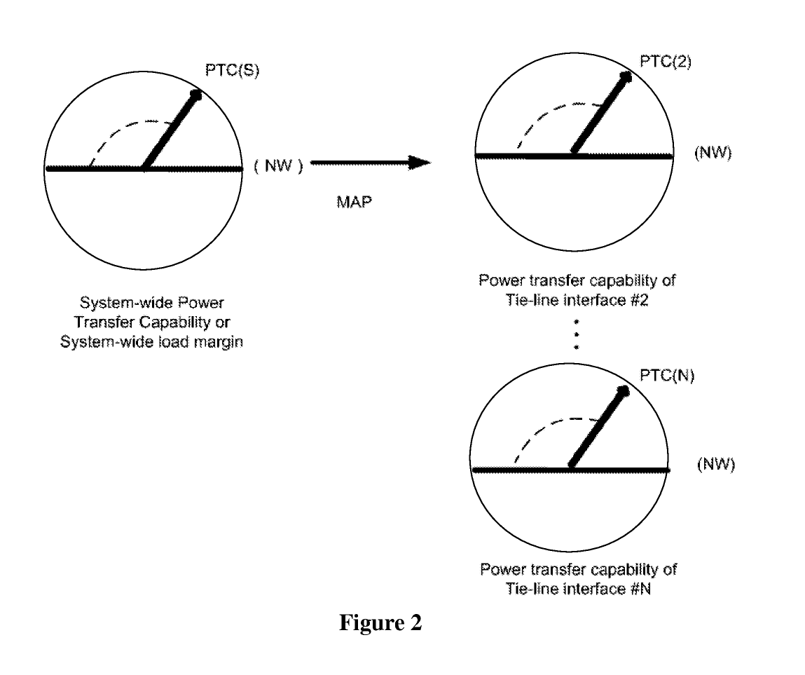

### DETAILED DESCRIPTION OF THE INVENTION

The Real-Time ATC system developed in this invention is designed to provide power system operators with critical information including the following:
(i) Assessment of real-time ATC of a power system subject to both static and transient stability constraints of a list of contingencies.
(ii) Available power transfer capability and power transfer limits at key interfaces subject to both static and transient stability constraints of a list of contingencies.
(iii) The limiting contingencies and binding constraints for power transfer limits.

The outputs of the real-time ATC system include the following:
Overall status of the system; i.e. system-wide ATC, and the corresponding binding constraints (line thermal limits, or bus voltage limits, or voltage stability (steady-state stability) constraints or transient stability constraints) and the limiting contingency.
power transfer limits at key interfaces, the corresponding limiting contingencies (contingency details such as fault type, fault location, and circuits lost) and the corresponding binding constraints.
available power transfer capability and the corresponding limiting contingencies (contingency details such as fault type, fault location, and circuits lost).
   The distinguished features of the real-time method include the following Functional Viewpoint:
1. It computes ATC and FCITC, and identifies the corresponding (the most severe) contingency, and the associated binding constraints.
2. It identifies and ranks the top severe contingencies in terms of their impacts on ATC and FCITC.
3. For each ranked contingency, it computes ATC and FCITC of the power system subject to the contingency and the associated binding constraint.
4. It identifies the bottlenecks of ATC in terms of locations of bottlenecks, types of binding constraint and the associated binding contingency.
5. It handles all the static security constraints of a given contingency list.
6. It facilitates the incorporations of the dynamic security constraints.
7. It determines the required ancillary services.

### Probabilistic Analysis:

8. It allows a probabilistic treatment of each contingency to compute ATC and FCITC.

### Model Viewpoint:

9. It is based on a full power system nonlinear modeling
10. It takes into account the effects of control devices
11. It models the general characteristic of power system operating environments

### Control Viewpoint

12. It offers a highly effective environment for the development of control schemes to increase ATC and FCITC.
13. It provides a platform to take proactive action in computing ATC and FCITC and to prepare remedy control.

PTC of an interconnected power system depends heavily on underlying power transactions. In fact, the PTC and its associated binding constraints of an interconnected power system can be very different for different proposed power transactions. Hence, it is important to specify the proposed power transaction in calculating the PTC with respect to the power transaction.

Given a set of proposed power transactions, the objective of a transfer capability computation is to determine the maximum transfer value for a proposed power transaction or simultaneous power transactions. The problem formulation upon which the calculation is based must have the following general characteristics:
(C1) it represents a realistic operating condition or expected future operating condition. To achieve (C1), the activation of the following control devices normally expected in any operating procedures should be included in the simulations: (i) Switchable shunts and static VAR compensators, (ii) ULTC Transformers, (iii) ULTC phase shifter, (iv) Static tap changer and phase shifter, (v) DC Network. In order to completely describe the actual power flow in the entire interconnected systems network and, in particular, the unintended electric power flows on these neighboring or adjacent systems known as parallel path flows, a detailed nonlinear power flow analysis of the interconnected system must be performed.
(C2) it conforms with the requirements of the transfer capability definitions by NERC. To achieve (C2), it is important to accurately represent the proposed power transaction.
(C3) it considers single contingency facility outages that result in conditions most restrictive to electric power transfers. To achieve (C3), the static and dynamic security assessments of the first contingency from a contingency list on an interconnected power system is required.

The basic information required for the system-wide PTC evaluations includes the following:
(1) the current operating condition (obtained from the state estimator and the topological analyzer);
(2) a base case power system model with control devices, reactive power generation limits;
(3) load forecast for the next period (say, next 15 minutes) of each bus;
(4) a set of proposed power transactions, such as (i) a point-to-point MW transaction, or (ii) a slice-of-the-system sale, or (iii) a network service, for the next period;
(5) generation scheduling (or generation participation factor) to accommodate load increases or/and to accommodate power transactions; and
(6) a list of credible contingencies.

In addition to the above basic information, the information of how to model the control actions during the process of step increases in loads and generations is required. These control actions include the static VAR compensator, TCSC, tap changer, synchronous condenser voltage/Mvar, LTC transformer voltage control, phase-shiftier controls, and capacitor/reactor voltage control, etc. . . . .

We present a method to represent a power transaction or a set of power transactions. We also discuss the notion of generation/load margin to a static security limit.

Given a load demand vector (i.e. real and reactive load demands at each load bus) and a real generation vector (i.e. real power generation at each generator bus), one can compute the state of the power system (the complex voltage at each bus) by solving the set of power flow equations.

Let P [symbol] =P [symbol] −P [symbol] and Q [symbol] =Q [symbol] −Q [symbol] . The lowercase g represents generation and the lowercase d represents load demand. The set of power flow equations can be represented in compact form as

$$f ( x ) = [ \begin{matrix}P ( x ) - P \\ Q ( x ) - Q\end{matrix} ] = 0 , where x = ( v , θ ) \qquad ( 1 )$$

Now one can investigate the steady-state behavior of the power system under slowly varying loading conditions and real power redispatch. For example, if one needs to trace the power system state from the base-case generation/load condition [P_{d} [symbol] , Q_{d} [symbol] , P_{g} [symbol] ] to a new generation/load condition [P_{d}¹, Q_{d}¹, P_{g}¹], then one can parameterize the set of power flow equations as such

F(x,λ)=f(x)−λb=0 (2)

where the generation/load vector b is

$$b ≡ [ \begin{matrix}{P}^{1} - {P}^{0} \\ {Q}^{1} - {Q}^{0}\end{matrix} ] \qquad ( 3 )$$

It follows that the parameterized power flow equations become the base-case power flow equations when λ=0,

$$F ( x , 0 ) = [ \begin{matrix}P ( x ) - {P}^{0} \\ Q ( x ) - {Q}^{0}\end{matrix} ] = 0 \qquad ( 4 )$$

And when λ=1, the power system is at the new generation/load condition [P_{d}¹, Q_{d}¹, P_{g}¹] and can be described by

$$F ( x , 1 ) = f ( x ) - b = [ \begin{matrix}P ( x ) - {P}^{1} \\ Q ( x ) - {Q}^{1}\end{matrix} ] = 0 \qquad ( 5 )$$

As shown in the above procedure, one can investigate the effects of varying real power generations as well as varying load demands on power system steady-state behaviors. In fact, one can parameterize any change in PQ loads in conjunction with any change in P generations by selecting an appropriate vector b.

Applying the above general setting to the problem of computing PTC of interconnected power systems, the vector b can be used to represent one or several of the following power transactions and transmission service:
Point-to-point MW transaction—the real power at one load bus of the receiving area varies while the others remain fixed and the real power at one generator bus of the sending area varies while the others remain fixed,
Slice-of-the-system sale—both the real and reactive power demand at a load bus of the receiving area vary and the real power generation at some collection of generators of the sending bus varies while the others are fixed,
Network service—the real and/or reactive power demands at some collection of load buses of the receiving area vary and the real power generation at some collection of generators of the sending bus varies while the others are fixed,
Reactive ancillary service—the reactive power demands at a specific or some collection of load buses of the receiving area vary and are balanced by the reactive generation within the same area or at other surrounding areas.

We shall call the vector b the proposed power transaction vector, and the scalar λ, the generation/load condition number. The proposed power transaction vector b can be used to represent a transaction involving simultaneous power transfers by summing each power transaction vector, i.e. b=Σbᵢ, i=1, 2, . . . where the vector represents the ith power transaction.

The introduction of the power transaction vector and the load generation condition number enable one to rigorously evaluate available transfer capability of an interconnected system satisfying the general characteristics (C1), (C2) and (C3) stated above. For instance, one can compute the maximum value of the generation/load condition number so that the resultant interconnected power system satisfies all the constraints, which are required in the general characteristics (C2) and (C3).

Due to the nonlinear nature of interconnected electric systems, power transfer capabilities between two areas and their associated binding constraints depend on a set of system conditions. The power transfer capabilities and their associated binding constraints can be significantly different for any other set of system conditions, such as a different set of system load demands, a different network configuration, a different power transaction, or a different generation dispatch pattern. Hence, transfer capability computations must be sufficient in system modeling and scope to ensure that all equipment as well as system limits of the entire interconnected systems network are properly taken into account.

In general, power transfers cannot be forced through pre-determined transmission paths, unless the paths are physically controlled by control devices such as phase-shifters. Therefore, power transfers will be distributed among all parallel paths according to the laws of physics. As a result, simple bi-lateral contracts between neighboring areas may not be sufficient to describe the actual power flow. Detailed nonlinear power system models must be used for analysis.

In addition, given a set of proposed power transactions, the binding constraint which limits the system's PTC can be the physical operating limits of an equipment/facility, or the bus voltage constraint in the entire system including the sending, the receiving as well as all neighboring areas, or the steady-state stability limit. The limiting equipment/facility, or the bus with voltage violation, or even the binding contingency may not occur in the two areas involving power transfers. To address this issue, a comprehensive modeling of the interconnected power system is necessary for the development of an effective on-line PTC method.

### Real-Time Static-Security Constrained PTC Method

We describe our invented method for computing real-time static security constrained power transfer limit (i.e. real-time static PTL) with respect to a specified generation/load variation vector, given a proposed power transaction or a proposed simultaneous power transactions such as (i) a point-to-point MW transaction, or (ii) a slice-of-the-system sale, or (iii) a network service, or (iv) a reactive ancillary service, and the following information:
(1) a base case power system model with control devices, reactive power generation limits, schemes of real power dispatches, say due to participation factor, etc. . . .
(2) the current operating condition (obtained from the state estimator and the topological analyzer),
(3) operating policy,
(4) a set of credible contingencies,
(5) voltage constraints, thermal-limit constraints, steady-state stability limit constraints, and
(6) transient stability constraints.

The real-time method of the invention computes the static-security constrained PTC (i.e. static PTC) for the proposed power transaction of the interconnected system with the following control laws and satisfying all the constraints stated above.

### Control Law

The real-time method of the invention allows the participation of generators, loads, ULTC taps, phase-shifter settings, shunt capacitors, and DC links as controls to maximize available transfer capability. The control laws can be classified as active control and passive control, where active control laws are the control laws whose objective function is to maximize power transfer capability through their control actions while passive control laws are the control laws whose objective function is to remove various types of security violations through their control actions which can also increase power transfer capability.

The actions of active control laws can be formulated as a constrained optimization problem whose objective function is the transfer capability while the actions of passive control laws can be formulated as a constrained optimization problem whose objective function is not the transfer capability.

### Identifying Binding Contingencies and Binding Constraints

It is important for the process of computing available transfer capability to take into account all credible contingencies. A simultaneous transfer capability solution can be regarded as secure only if it can sustain all credible contingency cases. The strategy of using effective schemes to rank all credible contingencies and of applying detailed analysis programs only to critical contingencies is widely accepted.

Adopting this strategy, the real-time method employs three look-ahead ranking schemes for identifying critical contingencies in terms of three static security constraints; i.e. thermal limits, voltage limits and steady-state stability limits. With these ranking schemes, the real-time method has the ability to:
(1) identify top binding contingencies,
(2) find the associated binding constraints, and
(3) compute the corresponding simultaneous available transfer capability.

### Three Fast Look-Ahead Schemes

Three fast and yet accurate look-ahead estimators which can identify and rank critical contingencies in the context of static security assessments are incorporated into the real-time method. One look-ahead estimator serves to rank the set of all credible contingencies in terms of load (or generation/load) to their branch MVA violations (i.e. thermal limit violations) and to identify the top few critical contingencies for thermal limit violation. Another look-ahead estimator ranks the set of all credible contingencies in terms of their load margins to system collapse (i.e. steady-state stability limit) and identifies the top few critical contingencies for violating steady-state stability limit. The third estimator ranks all credible contingencies in terms of their load margins to bus voltage violation and identifies the few top critical contingencies for voltage violation. These three look-ahead estimators are briefly described in the next section.

Given (i) the current operating condition (obtained from the state estimator and the topological analyzer), (ii) a proposed power transaction or a proposed set of simultaneous power transactions, (iii) a base case power system model with control devices, reactive power generation limits, schemes of real power dispatches, say due to participation factor, etc. (iv) and voltage constraints, thermal-limit constraints, steady-state stability limits (v) a credible contingency from a contingency list, the three look-ahead estimators estimate the following three load margins to the three static security limits, along the proposed power transaction vector b for the parameterized power system (parameterized along the direction of the proposed power transaction) for the power system subject to the contingency.

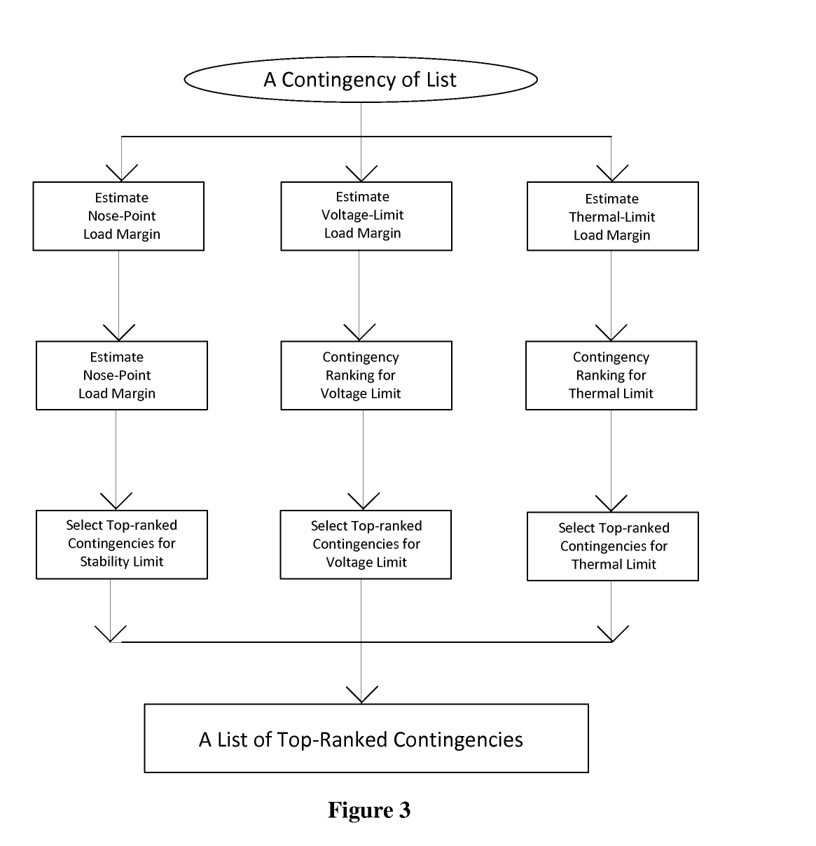

FIG. 3 shows diagrams of the proposed three schemes for ranking a list of contingencies in terms of three types of load margins—nose-point, voltage limit and thermal limit. These load margins are:
(1) the nose-point load margin, say λⁿ, to measure the distance (MW and/or MVAR) between the current operating point to the nose point of the parameterized power system subject to the contingency,
(2) a voltage-limit load margin, say λ^{v}, to measure the distance (MW and/or MVAR) between the current operating point to the state of the parameterized power system subject to the contingency at which the voltage limit constraint at some bus is violated, and
(3) a thermal-limit load margin, say λ^{t}, to measure the distance (MW and/or MVAR) between the current operating point to the state of the parameterized power system subject to the contingency at which the thermal limit constraint of some branches is violated.

Each of the above three load margins is then applied to rank the contingency list for the following three categories:
Contingency ranking for steady-state limit,
Contingency ranking for voltage violation, and
Contingency ranking for thermal violation.

A list of top-ranked contingencies can thus be composed by selecting the top-ranked contingencies from each category.

Apply the continuation power flow (CPFLOW) method to each top-ranked contingency to obtain the so-called P-V curve, or P-Q-V curve and find the load margins to the steady-state limit, voltage violation point and the thermal violation point. The smallest one is the load margin of the top-ranked contingency.

### Solution Method

The solution method for the real-time method of the invention to evaluate the static PTC of an interconnected power system with respect to a set of proposed power transactions subject to static security constraints is presented below.
Stage 1: Initialization: Build the power transfer vector to represent (mathematically) the proposed power transfer transaction and form the parameterized power flow equations by incorporating the power transfer vector b into the base-case power flow equations.
Stage 2: Contingency Ranking for Static Security Violation
Stage 3: Compute first-contingency PTC and identify the corresponding binding contingency.
Stage 4: Rank Contingency-constrained PTCs and FCITCs
Stage 5: Output Analysis

A detailed description of the steps in each stage is described below.

### Stage 1: Initialization

1.1 Build the power transfer vector b to represent (mathematically) the proposed power transfer transaction.
1.2 Form the parameterized power flow equations by incorporating the power transfer vector b into the base-case power flow equations: f(x)−λb=0
1.3 Initialize the parameter, (i.e. generation/load condition number) λ by setting λ=λ [symbol] to the base case.

### Stage 2: Contingency Ranking for Static Security Violation

2.1 Use a look-ahead scheme to rank the set of contingencies L in terms of branch MVA violation. Let the ranked set of contingencies be L(mva).
2.2 Use a look-ahead scheme to rank the set of contingencies L in terms of bus voltage violation. Let the ranked set of contingencies be L(volt).
2.3 Use a look-ahead scheme to rank the set of contingencies L in terms of load margin. Let the ranked set of contingencies be L(margin)

### Stage 3: Compute First-Contingency PTC and Identify the Corresponding Binding Contingency.

3.1 Select the top Nₐ contingencies from the ordered set L(mva), the top N_{b} contingencies from the ordered set L(volt), and the top N_{c} contingencies from the ordered set L(margin). Renumber these contingencies into l₁, l₂ . . . , l_{N}_{ₐ}_{+N}_{_{b}}_{+N}_{_{c}} and if there are any sets of duplicate contingencies, eliminate all but one of each set of duplicate contingencies. Define a new set L_{static}▴{l₀, l [symbol] , l_{N}_{ₜₒₜₐₗ} [symbol] }, where l₀ represents the base case power system.
3.2 For each contingency in L_{static}, for example lᵢ, i=0, 1, 2, . . . , total, do steps 3.2.1˜3.2.4:
   3.2.1 Set j=0
   3.2.2 Use CPFLOW to compute the solutions of the parameterized power flow equations under contingency l_{g} for each generation/load condition number λⱼ=λⱼ [symbol] +Δλⱼ [symbol] , where Δλⱼ=0 if j=0; otherwise Δλⱼ is determined by the step-size control in CPFLOW. If the post-contingency power flow solution [X(l [symbol] λ] [symbol] ) satisfies the following static security constraints
voltage: V [symbol] ≦V(lᵥλⱼ)≦V^{M}
line current: I^{m}≦I(lᵥλⱼ)≦I^{M}
facility loading: g(lᵥλⱼ)≦0
then set j=j+1 and repeat Step 3.2.; otherwise, set Cbind=the corresponding violated constraints and go to Step 3.2.3.
   3.2.3 If |λ [symbol] −λⱼ₋₁|<g, go to Step 3.2.4; otherwise, set

$$\text{?} = \frac{\text{?}}{2} \\ \text{?} \text{indicates text missing or illegible when filed} \qquad$$

and use CPFLOW to compute the solutions of the parameterized power flow equations under contingency lᵢ for the generation/load condition number λⱼ= λ̅ⱼ̅. If the post-contingency power flow solution X(l [symbol] , λ̅ [symbol] ) satisfies the static security constraints, then set λⱼ₋₁= λ̅ⱼ and repeat Step 3.2.3; otherwise set λⱼ= λ̅ⱼ̅, and Cbind=the corresponding violated constraints and go to Step 3.2.3.
3.2.4 Record the contingency lⱼ, the generation/load condition number λ̅ⱼ=λⱼ₋₁ the corresponding violated constraints CVⱼ. Hence, the (first-contingency) available transfer capability under contingency lⱼ is λ̅ⱼ−λ [symbol] with the binding constraint CVⱼ.
3.2.5 If t<Nₜₒₜₐₗ, set i=i+1 and go to Step 3.2.1; otherwise, go to Stage 4.

### Stage 4: Rank Contingency-Constrained PTCs and FCITCs:

4.1 Rank the set L_{static} according to each value λ̅ⱼ obtained in Step 3.2.4 and let the ranked contingency set be L̅_{static}=(l₁, l₂, . . . , lₜₒₜₐₗ) such that λ̅₁̅≧ λ̅₂̅≧ . . . ≧ λ̅ₜₒₜₐₗ.
4.2 The first-contingency PTC (or FCITC) subject to static voltage stability constraints and static security constraints of the contingency set L is λₜₒₜₐₗ=( λ̅ₜₒₜₐₗ−λ₀), the binding contingency lₜₒₜₐₗ and the associated violated constraint is CVₜₒₜₐₗ.
4.3 The PTC, under contingency Iⱼ, is λⱼ=( λ̅ⱼ−λ₀) with the binding constraint CVⱼ, for j=1, 2, . . . , total−1□

### Stage 5: Output Analysis

Output the PTC, FCITC for the power system with the proposed power transactions under each binding contingency and the associated violated constraints. PTC can be expressed in a number of ways.
   It can be expressed on terms of the amount of PTC between sending areas and receiving areas.
   On some occasions, it is useful from monitoring and control viewpoint to represent PTC in terms of pre-contingency interface power flows (i.e. the base-case interface power flows) of some transmission interface.

We explain the physical meaning of the value λ̅ⱼ in Stage 4 of the proposed solution algorithm as the transaction-dependent PTC for the power system subject to the contingency, say j.

Physically, if λ̅ⱼ is greater than 1.0, then it means that the transmission network is able to transfer the proposed power transactions in a reliable manner, should the contingency j occur. In addition, the (normalized) operating margin of the power system with the proposed power transactions is λ̅ⱼ−1.0.

On the other hand, the transmission network is unable to transfer the proposed power transactions, should the contingency j occur, if λ̅ⱼ is less than 1.0. In this case, the amount of reliable power transfer is λ̅ⱼ% of the proposed power transactions. For example, if λ̅ⱼ equals 0.7, then the available transfer capability for the proposed power transactions is 70% of the proposed power transactions.

This (normalized) operating margin can be translated into operational guidelines as follows: the system can reliably transfer the proposed power transaction. In addition, the transmission network can transfer additional ( λ̅ⱼ−1.0) % of the original proposed power transaction in a reliable manner.

The static PTC can be expressed in several ways. It is sometimes useful to represent the static PTC in terms of pre-contingency interface power flow (i.e. the base-case interface power flow) at the limit point. The calculated system-wide static PTC is then mapped into each interface static PTC.

### Numerical Studies

We consider a 15005-bus interconnected power system containing about 2400 generators, 16,000 transmission lines, 8,000 loads, 4000 fixed transformers, 2400 fixed shunts, 3000 ULTC transformers, 800 switchable shunts, and other control devices such as fixed and ULTC phase shifters, etc.

Given a base case of the interconnected power system with a secure operating point, a proposed power transaction described by transmitting 1300 MW real power from area A to area B by decreasing all the real power generations of area B uniformly to zero (24 generators are scaled down to 0 MW) and increasing real power generations of area A uniformly to supply the loads of Area B (the area-wide generation of Area A is scaled properly), we apply the real-time method to evaluate the real power transfer capability from area A to area B of the interconnected power system subject to a contingency list which is a set of transmission line or generator outages.

Three cutsets of 500 KV transmission lines were selected and the corresponding sum of the line flows was defined as the interface line flows.

In this numerical study, the PTC is expressed in terms of either (i) power transfer capability between the sending area and the receiving area, or (ii) the pre-contingency power flow of the three interface flows.

The three fast look-ahead estimators were applied to the contingency list. The top five most serious contingencies captured by each look-ahead estimator and the corresponding estimated load margin are listed in Table 1, Table 2 and Table 3, respectively. In these three tables, the contingency with the sign * is a generator trip.

TABLE 1
The five most serious contingencies according to
their impacts on the load margins to the stead-state
stability limit and the corresponding load margin.

| | Estimated Load margin | Estimated |
|---|---|---|
| Contingency | (MW) | Lambda |
| 32-6830 | 933 | 0.728 |
| 4364-6831 | 1043 | 0.808 |
| 85-4323 | 1053 | 0.81 |
| *4523 | 1053 | 0.81 |
| *4496 | 1057 | 0.813 |

TABLE 2
The five most serious contingencies according to their impacts on the load
margins to the thermal limit and the corresponding load margin.

| | | Estimated |
|---|---|---|
| Contingency | Estimated margin (MW) | Lambda |
| 89389-89392 | 194 | 0.149 |
| *289 | 566 | 0.435 |
| 89394-104 | 681 | 0.524 |
| *7498 | 746 | 0.574 |
| *89418 | 785 | 0.604 |

TABLE 3
The five most serious contingencies according to their impacts
on the load margins to the stead-state stability limit and
the corresponding load margin.

| | | Estimated |
|---|---|---|
| Contingency | Estimated margin (MW) | Lambda |
| 4364-6831 | 680 | 0.523 |
| 85-4323 | 748 | 0.575 |
| 32-6830 | 754 | 0.58 |
| *7498 | 759 | 0.584 |
| 89386-89387 | 759 | 0.584 |

Since 4 of 15 contingencies are redundant, there are only 11 contingencies that require further study. A detailed analysis based on the continuation power flow (CPFLOW) was performed for each of these 11 contingencies to compute the PTC and to identify the corresponding binding constraint. Note that the participation of all control devices and the physical constraints of these control devices are taken into account in the process of continuation power flow study.

The final results of ATC, which is the difference between the PTC and the current power flow with respect to the proposed power transaction along with the corresponding binding contingency and the corresponding binding constraints are shown in Table 4.

TABLE 4
Output Analysis of PTC computation

| | | Pre-contingency | | | | | |
|---|---|---|---|---|---|---|---|
| | | Interface power flow | | | | | |
| The top eight | | of | | | | | |
| serious | Contingency | three interfaces (MW) | | | Corresponding | Binding Constraints | |
| Contingency | Location | East | Central | West | ATC (MW) | Type | location |
| Base Case | Base Case | 5552 | 2247 | 4473 | 913 | Voltage | 7084 |
| The most serious | 89389-89392 | 5422 | 2203 | 4445 | 234 | Thermal | 3687-3337 |
| 2nd most serious | 89394-104 | 5478 | 2218 | 4452 | 584 | Thermal | 37-276, 37-277 |
| 3rd most serious | 4364-6831 | 5531 | 2237 | 4465 | 820 | Voltage | 6807, 6808, 7804 |
| 4th most serious | 32-6830 | 5537 | 2240 | 4467 | 845 | Voltage | 6807, 6808, 7804 |
| 5th most serious | *7498 | 5538 | 2241 | 4468 | 857 | Thermal | 37-276, 37-277 |
| 6th most serious | 85-4323 | 5541 | 2242 | 4468 | 869 | Voltage | 7804 |
| 7th most serious | *4496 | 5543 | 2243 | 4469 | 883 | Thermal | 37-276, 37-277 |
| 8th most serious | 89386-89387 | 5549 | 2246 | 4472 | 898 | Thermal | 37-276, 37-277 |

The numerical simulation shows that the ATC for the proposed power transaction, under the assumed set of contingencies, is 234 MW between the sending area and the receiving area (instead of 1300 MW). The corresponding contingency (i.e. 89389-89392) is the binding contingency. Equivalently, the ATC of the proposed transaction is 5422 MW for the east interface, 2203 MW for the central interface, and 4445 MW for the west interface.

It is interesting to note that the constrained east interface line flow under this contingency is the smallest among the constrained east interface line flows of the contingencies considered. This is also true for the constrained central interface line flow and the constrained west interface line flow.

The real-time method of the invention can compute each ATC with the corresponding binding contingency as a by-product and the associated violated constraint in an ‘increasing’ order as shown in Table 4. This piece of information is useful for decision-making personnel to take a proactive approach to measure the transfer capability of the network.

For instance, the ATC of the study system without the consideration of the contingency (89389-89392) is 584 MW. If the probability of the occurrence of contingency 89389-89392 is low, then it may be reasonable to post the ATC as 584 MW and, in the meantime, a remedy control scheme can be prepared in advance should contingency 89389-89392 occur.

Likewise, the ATC of the study system without the consideration of contingencies 89389-89392 & 89394-104 is 820 MW. If the probability of the occurrence of either contingency 89389-89392 or 89394-104 is low, then it may be reasonable to post the ATC as 820 MW and, in the meantime, a remedy control scheme can be prepared in advance should contingencies 89389-89392 and/or 89394-104 occur.

It should be also pointed out that this real-time method also allows (via the establishment of Table 4) a probabilistic treatment of each contingency and the associated risk management. Economic factors can also be linked to Table 4.

### Real-TimeStatic PTC in 2-Dimensional Nomogram

A static PTC nomogram is a two-dimensional display of static PTC in terms of two interface flows. Nomograms provide vital information for power system operators to operate power systems within power transmission static security limits and with a ‘comfort zone’. A nomogram always involves two interface paths. In computing a nomogram, we first need to associate one interface path with the X axis and the other interface path with the Y axis. Then we separate all source generators involved in the stress pattern into two groups. The source group that is responsible for the flow change in the X axis path is classified as group X, which is denoted as G₁. The source group that is responsible for the power flow change in the Y axis path is classified as group Y, which is denoted as G₂.

We compute the static PTC nomogram in the following way. We at first create two independent base generation vectors for b_{g1}, b_{g2} G₁ and G₂ respectively. Then, we create two independent coefficients for a₁, a₂ respectively. The overall generation vector considering both source groups will be:

b_{g}=a₁b_{g1}+a₂b_{g2} (6)

By assigning a₁, a₂ different values, we create a family of generation/load stress patterns, which spans the entire feasible generation/load stress space. For each generation/load stress pattern, we use the CPFLOW to compute the voltage stability load margin (i.e. the boundary of the nomogram along the stress pattern).

The proposed solution method to compute the static PTC nomogram is as follows:
Step 1: Separate source generators into two groups G₁ and G₂ and assign a₁=0 and a₂=1
Step 2: Compute b_{g} using the equation:

b_{g}=a₁b_{g1}+a₂b_{g2} (6)
Step 3: Use the proposed real-time method to compute the (one-dimensional) system-wide static PTC and the corresponding interface static PTC's along the direction b_{g}.
Step 4: Assign different values for a₁ and a₂ in the equation of step 2 and repeat Step 2: Compute b_{g} using the equation:

b_{g}=a₁b_{g1}+a_{g}b_{g2} (6)
to Step 3 to compute all points on the nomogram boundary (i.e. curve).
Step 5: Export the static PTC nomogram curve and the corresponding limiting contingency of each computed point on the nomogram boundary.

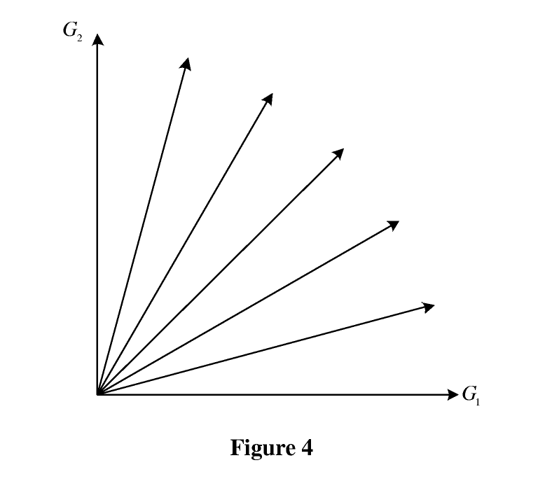

FIG. 4 shows a graph of how a stress pattern spans the entire feasible generation/load stress space.

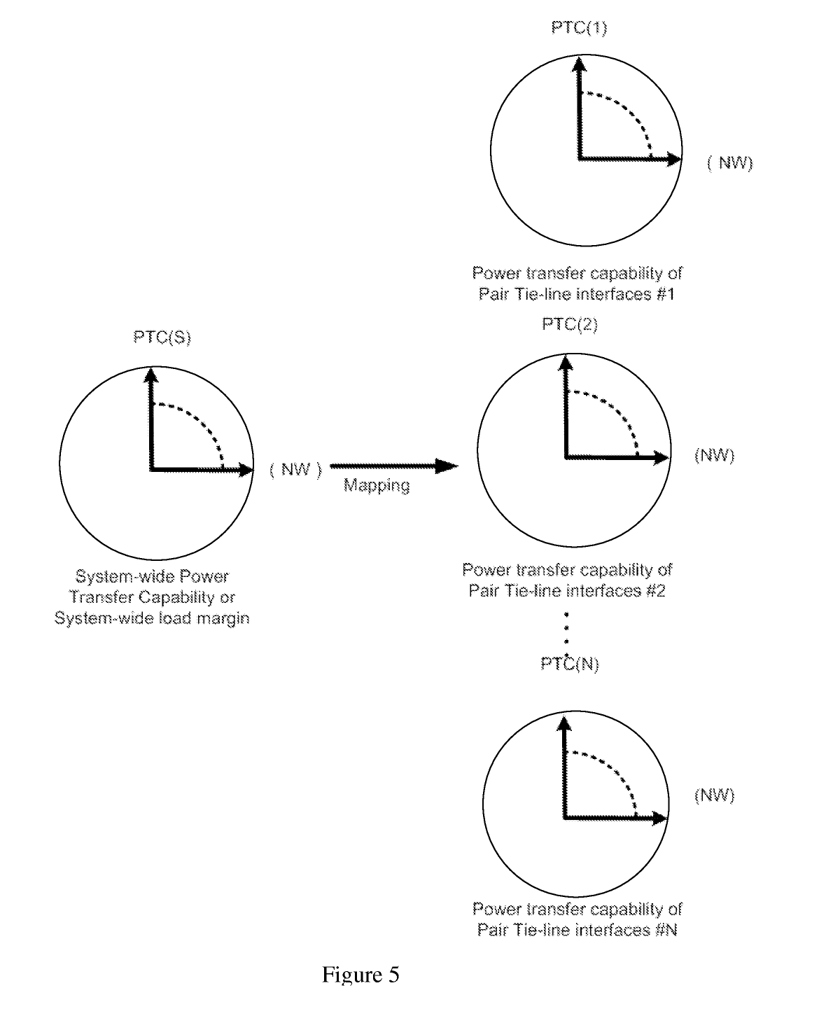

The static PTC nomogram can be expressed in several ways. It is sometimes useful to represent the static PTC nomogram in terms of pre-contingency interface power flow (i.e. the base-case interface power flow) at the limit point. The calculated system-wide static PTC nomogram is then mapped into each interface static PTC nomogram. FIG. 5 shows diagrams of how a system-wide static PTC nomogram is mapped into each pair of tie-line interfaces static PTC nomogram.

### Real-Time Static ATC Determination System

The real-time ATC is the difference between the real-time PTC and the current actual power flow. To provide a real-time static ATC (i.e. ATC subject to static security constraints and voltage security constraints), it is necessary to have some real-time information regarding a system's operating conditions This invention proposes to apply a wide-area measurement system (WAMS) such as phasor measurement units (PMUs) installed at selected tie-lines and buses to obtain the required real-time real power and reactive power information.

One central topic in the area of wide-area measurement is the utilization of this new type of measurement (as opposed to traditional SCADA measurements). Phasor data, precisely time-synchronized data at a high data rate, provide a wide-area view of current power system conditions. To fill the gap between real-time phasor measurements and real-time operation applications, we propose to develop an integrated system which contains a wide-area measurement system and the real-time PTC system for an accurate determination of real-time PTC. This real-time PTC determination ensures power system security and reliability while offers better power system asset utilization and economic benefits.

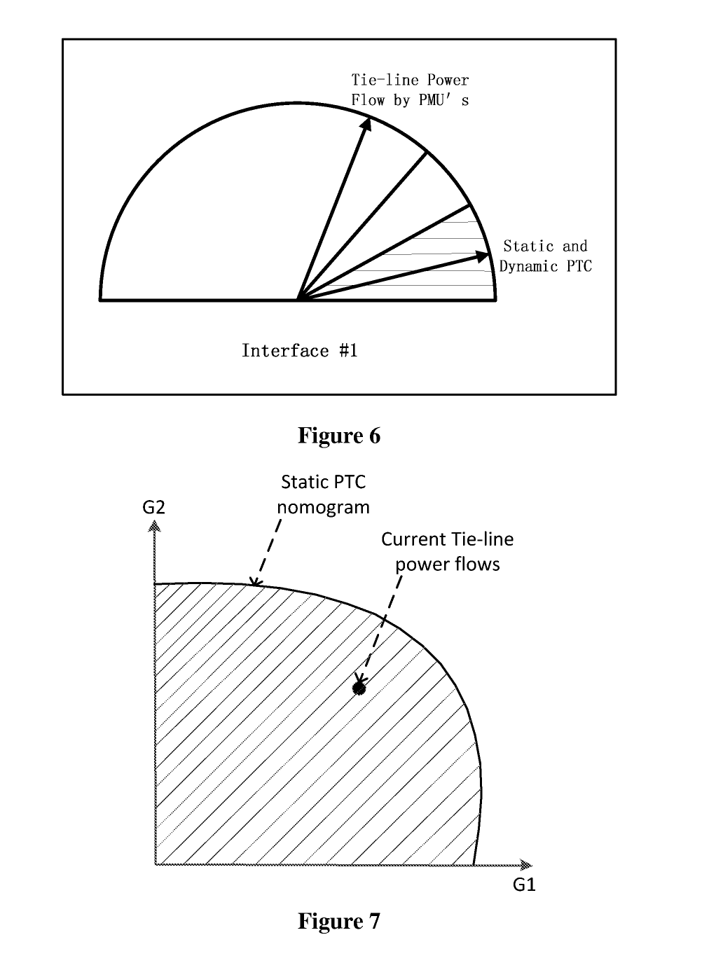

FIG. 6 shows the tie-line power flow of interface #1 is measured by PMU's placed across interface #1 while the static PTC of interface #1 is computed by the proposed method for computing the real-time static PTC. The difference between the static PTC and the real-time tie-line power flow is the real-time static ATC.

FIG. 7 shows the tie-line power flow of interface #i is measured by PMU's placed across interface #i while the tie-line power flow of interface #j is measured by PMU's placed across interface #j. The static PTC nomogram for interfaces #i and #j is computed by the invented method. The distance between the static PTC nomogram and the real-time tie-line power flows is the real-time static ATC in 2-dimension.

Given an operating point (derived from a state estimator), a network topology, a set of pre-determined interfaces and a contingency list associated with each interface, we develop a PMU-assisted, real-time static ATC determination system for each interface. The output of this system can be expressed as the following:
Real-time Static ATC in One-dimensional maps (shown in FIG. 6),
Real-time Static ATC in Two-dimensional maps (i.e. in nomogram, as shown in FIG. 7).

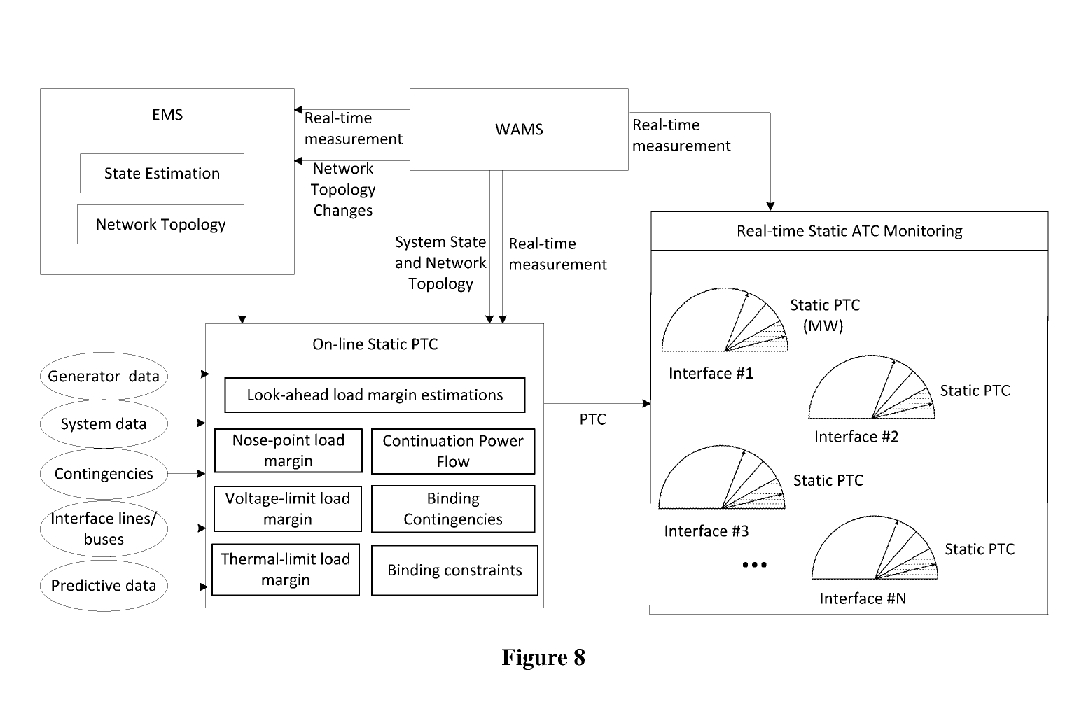

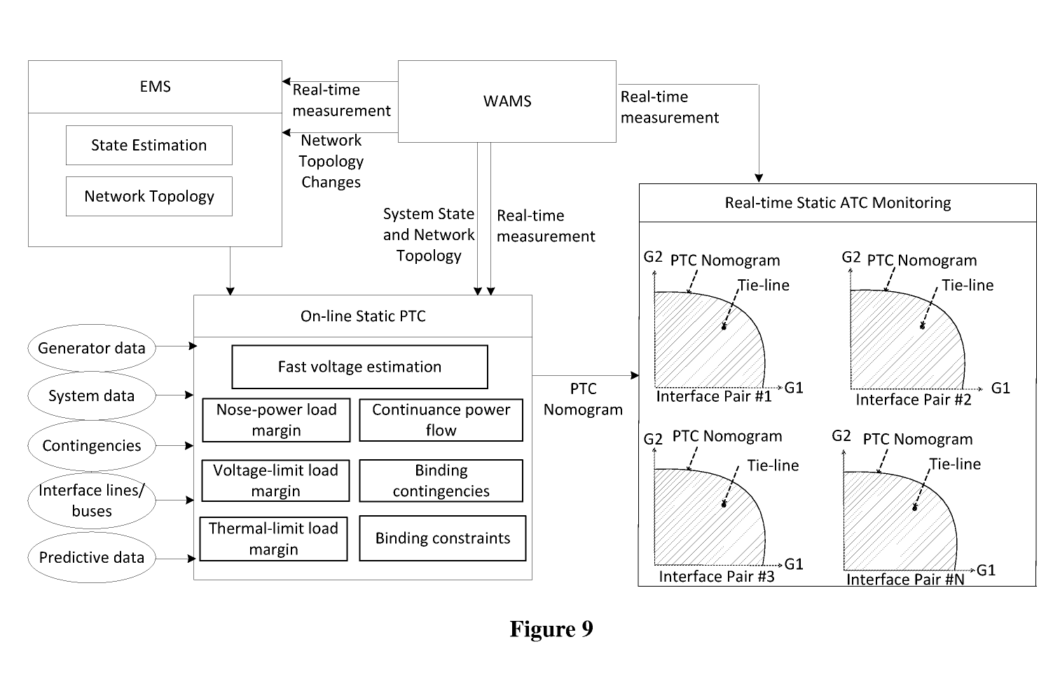

The architecture of the invented method for determining the real-time static ATC is shown in FIG. 8 and in FIG. 9 respectively for different expressions of ATCs.

There are four key components in this real-time static ATC determination system:
(1) stator estimator and network topology analyzer from an energy management system;
(2) the invented real-time static power transfer capability measurement system;
(3) the real-time measurement units, PMUs, placed various locations including a set of pre-determined interfaces; and
(4) the real-time ATC display system with both one-dimensional and two-dimensional ATC monitoring system.

It should be pointed out that the solution methods of the invented system can also determine the top-ranked interface static power transfer limit of each selected interface under the contingency list associated with each interface.

This real-time static ATC determination system has the following features:
(1) The real-time static security ATC calculation methodology determines the top-ranked system-wide power transfer limits subject to static security constraints of a contingency list.
(2) The system identifies, for each top-ranked power transfer limit, the corresponding limiting contingency and the corresponding binding constraint.
(3) The system maps each top-ranked system-wide power transfer limit into the power transfer limit of each selected tie-line interface under the contingency.
(4) The real-time measurement of power flow across each selected tie-line interface is obtained from the installed PMUs. For each limiting contingency, the difference between the corresponding power transfer limit and the current power transfer is the real-time available transfer capability of the system associated with the top limiting contingency and the corresponding binding constraint expressed as the power flow across each interface.

### Real-Time Dynamic PTC

In the following discussion, we define the real-time dynamic power transfer capability of a power system.

The transient-stability-limit power transfer capability (PTC), or termed dynamic PTC is defined as the (minimum) distance (i.e. load margin in terms of MW and/or MVAR) from the current real-time operating point to the state vector of the base-case P-V curve, along a stress pattern (or a given power transaction) on which at least one contingency, from a contingency list, would result in transient instability.

We note that the dynamic PTC should be smaller than the nose-point load margin of the base-case power system since the transient-stability-limit load margin is not defined when its value is greater than the nose-point load margin of the base-case power system. The task of computing the transient-stability-limit load margin with respect to a set of credible contingencies is rather challenging.

In this invention, we develop a methodology, termed the BCU-limiter, which can quickly and accurately compute the PTC limited by the transient stability of credible contingencies (i.e. the real-time dynamic PTC). This BCU-limiter computes, given a proposed power transaction, the amount of power transfers a power system can withstand before its transient stability limit is reached.

In addition, the BCU-limiter can rank a given list of contingencies, in terms of their load margins, to transient stability limits and compute the corresponding PTC. This BCU-limiter is an integration of the BCU methods, the BCU classifiers, the continuation power flow (CPFLOW) method and a time-domain simulation method.

Given an operating point, the BCU-limiter not only performs power system dynamic security assessments and ranking but also computes the PTC limited by the transient stability of credible contingencies.

The amount of required calculation is huge and the following requirements are important for computing transient stability constrained PTC under a list of contingencies.
[1] Accuracy: the limiting contingencies to which the PTC is subject must be captured.
[2] Performance: the PTC computation involves transient stability assessment at multiple loading conditions on the base-case P-V curve. This fact, together with the fact that the size of contingency list can be very large, imply that PTC computation indeed requires significant amount of computational efforts.

This invention designs an effective search algorithm that enables one to fast determine real-time dynamic PTC. The operating points chosen from the P-V curves on which the transient stability analysis of a contingency list is to be performed has a huge influence on the efficiency of the overall computation engine. We next propose an energy-margin-based search method to select the next operating point between two known operating points on a P-V curve.

### Energy-margin-based Bisection Search Method

Step 1: Apply the BCU method to compute the energy margin of contingency i at the base-case λ=λ₀. Let the energy margin of contingency i be Wᵢ^{(λ}^{₀}⁾. If Wᵢ^{(λ}^{₀}⁾>0, then contingency i is stable, otherwise, it may be unstable.
Step 2: Apply the BCU method to compute the energy margin of contingency i at another loading condition, say λ= [symbol] 1. Let the energy margin of contingency i be Wᵢ [symbol] ^{(λ}^{₁}⁾. If Wᵢ [symbol] ^{(λ}^{₁}⁾<0 then contingency i is unstable at the loading condition λ=λ₁. Without loss of generality, it is assumed that Wᵢ [symbol] ^{(λ}^{₁}⁾<0.
Step 3: The power transfer limit (PTL) relative to contingency i lies between the two loading conditions λ₀ and λ₁.
Step 4: There exist several one-dimensional search algorithms, for example,

Bracketing and Bisection algorithms, secant algorithms, Ridder's algorithm etc. to identify the PTL subject to contingency i. Here, we illustrate the Ridder's algorithm to find the root of the following equation

Wᵢ(λ)=0, with Wᵢ(λ₁)<0 and Wᵢ(λ₁ [symbol] )>0 and λε[λ₀, λ₁]
where Wᵢ(.) is an energy function for contingency i.
Step 5: Compute a new loading condition

$$\text{?} = \frac{{λ}_{0} + {λ}_{1}}{2} \\ \text{?} \text{indicates text missing or illegible when filed} \qquad$$

and compute the energy margin at the new loading condition Wᵢ(λ₂).
Step 6: Compute the next loading level

$$\text{?} - \text{?} + \frac{\text{?}}{\sqrt{\text{?} - {W}_{□} ( {λ}_{0} ) {W}_{□} ( {λ}_{1} )}} \\ \text{?} \text{indicates text missing or illegible when filed} \qquad$$

Step 7: The next loading condition to be evaluated for transfer stability assessment is at λ_{□}=λ

[symbol]

Another one-dimensional search method for implementing Step 4 of the above algorithm is the golden bisection method, which is an one dimensional search method used for finding the optimal solution of a real-valued unimodal function. A unimodal function F(x) has the property that there is an unique x* on a given interval [a,b] such that F(x*) is the only minimum of F(x) on the interval, and F(x) is strictly decreasing for x≦x* and strictly increasing for x≧x*. The significance of this property is that it enables us to refine an interval containing a solution by computing sample values of the solution within the interval and discarding portions of the interval according to the function values obtained.

### Computing Real-Time Dynamic PTC

We now describe a real-time methodology, termed BCU-limiter, to compute real-time dynamic PTC.
Step 1: Apply the Continuation Power Flow (CPFLOW) method to compute the P-V curve for the base-case power system for a given generation/load variation pattern (i.e. for a proposed power transaction).
Step 2: Apply the TEPCO-BCU method described below to the base-case operating point to perform transient stability analysis of the operating point subject to a contingency list.
Step 3: If there is an insecure or critical contingency at the (current) base-case operating point, then the dynamic PTC is zero for the proposed power transaction, otherwise, set the base-case operating point as the lower bound of the dynamic PTC and record the corresponding critical contingencies and their corresponding energy margin, and continue to the next step.
Step 4: Apply the TEPCO-BCU method to the base-case nose point to perform a transient stability analysis subject to the entire contingency list.
Step 5: If there is no insecure or critical contingency at the base-case nose point, then the dynamic PTC is greater than the static PTC for the proposed power transaction, output the dynamic PTC as the same value of static PTC and stop; otherwise, set the base-case nose point as the upper bound of the dynamic PTC and record the corresponding insecure and critical contingencies and their corresponding energy margin, and continue to the next step.
Step 6: Select a loading condition on the P-V curve between the lower bound and the upper bound of the dynamic PTCs based on the energy-margin golden bisection search algorithm.
Step 7: Apply the TEPCO-BCU engine to the selected loading condition of Step 6 to perform transient stability analysis subject to the newly-updated contingency list (such as a selected set of contingencies based on the insecure and critical contingencies at both the upper bound operating point and lower bound operating point).
Step 8: If one or more insecure contingencies are detected, set the current loading condition as the upper bound of the dynamic PTC; otherwise, update the lower bound of dynamic PTC by the currently selected loading condition. If the difference between the lower bound and upper bound of the dynamic PTC is larger than a specified number, then go to Step 6.
Step 9: Export the top-limiting contingencies and compute the corresponding dynamic PTCs.

We note that the TEPCO-BCU method is the method described in the following patents, which are incorporated herein by reference:
U.S. Pat. No. 7,483,826; “Group-Based BCU Methods for real-time Dynamical Security Assessments and Energy Margin Calculations of Practical Power Systems” Date of patent, Jan. 27, 2009 (Inventors: Hsiao-Dong Chiang, Hua Li, Yasuyuki Tada, Tsuyoshi Takazawa, Takeshi Yamada, Atsushi Kurit, and Kaoru Koyanagi)
U.S. Pat. No. 7,761,402; “Group-Based BCU Methods for real-time Dynamical Security Assessments and Energy Margin Calculations of Practical Power Systems” Date of patent, Jul. 20, 2010 (Inventors: Hsiao-Dong Chiang, Hua Li, Yasuyuki Tada, Tsuyoshi Takazawa, Takeshi Yamada, Atsushi Kurit, and Kaoru Koyanagi)
Japan Patent 4,276,090; “Method and System for real-time Dynamical Screening of Electric Power System” Date of Patent, Mar. 13, 2009 (Application number 2003-586902, filing date Apr. 21, 2003), (Inventors: Hsiao-Dong Chiang, Atsushi Kurita, Hiroshi Okamoto, Ryuya Tanabe, Yasuyuki Tada, Kaoru Koyanagi, and Yicheng Zhou)
Japan, Patent 4,611,908; “Group-Based BCU Methods for real-time Dynamical Security Assessments and Energy Margin Calculations of Practical Power Systems” Date of Patent, Oct. 22, 2010 (Application number 2006-031327, filing date Feb. 8, 2006), (Inventors: Hsiao-Dong Chiang, Hua Li, Yasuyuki Tada, Tsuyoshi Takazawa, Takeshi Yamada, Atsushi Kurit, and Kaoru Koyanagi)
Peoples of Republic of China, Patent ZL 038,089,55.6; “Method and System for real-time Dynamical Screening of Electric Power System” Date of Patent, Dec. 10, 2008 (filing date Apr. 21, 2003), (Inventors: Hsiao-Dong Chiang, Atsushi Kurita, Hiroshi Okamoto, Ryuya Tanabe, Yasuyuki Tada, Kaoru Koyanagi, and Yicheng Zhou)

The TEPCO-BCU engine is composed of two major functions:
[1] Fast contingency screening function. It processes the full set of credible contingencies at a given system condition. Each contingency will be identified as potentially unstable or definitely stable. Definitely stable contingencies are then assigned with appropriate energy function values (i.e. stability margins) according to BCU method and are eliminated from further stability analysis. Potentially unstable contingencies are then sent to the detailed time-domain stability analysis module for detailed stability assessment. The output of this fast contingency screening module will be a short list of the following:
   (a) Potential unstable contingencies with an energy margin
   (b) Critical stable contingencies with an energy margin
[2]. Detailed transient stability analysis function. This function mainly employs the time-domain simulation method for detailed transient stability analysis to accurately assess the stability/instability property of the screened (i.e. potentially unstable) set of contingencies so that the transient stability of the screened contingencies can be determined.

The dynamic PTC can be expressed in several ways. It is sometimes useful to represent the dynamic PTC in terms of pre-contingency interface power flow (i.e. the base-case interface power flow) at the limit operating point. The system-wide dynamic PTC is then mapped into each interface dynamic PTC.

### Numerical Example

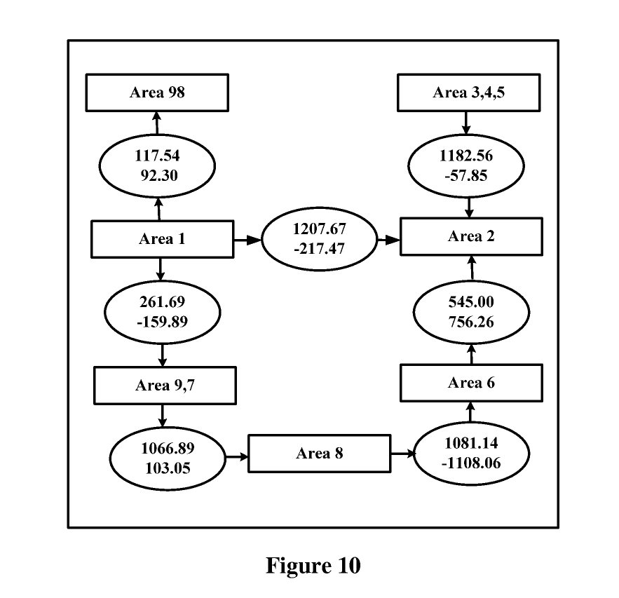

The 65-generator system represents a subsystem of a major interconnected grid in the North America. This subsystem is composed of nine areas with 1135 buses and 2216 transmission lines. The base-case area interchange power flows are graphically displayed in FIG. 10.

There are seven tie lines between area 1 and area 2 with interchange power flow of 1207.67 MW and −217.47 MVar from Area 1 and Area 2. One good of this study is to find the real power transfer limit (i.e. PTC) from area 1 to area 2 under the transient stability constraint with the following operating scenario:

Area 2 generators decreases from the base-case value 17030.79 MW to 12091 MW; uniformly among all the generators in Area while Area 1 generation uniformly increases from 19365.88 MW to 24400 MW to compensate the power deficit in Area 2. The transmission losses incurred from this power transfer from Area 1 to Area 2 are compensated by the Area slack buses in Area 1 and Area 2.

The system-wide dynamic PTC and the interface-flow dynamic PTC between Area 1 and Area 2 are to be computed. The interface-flow between Area 1 and Area 2 is defined as the sum of the power flows on the seven tie lines. The treatment of reactive power limits, real power generations due to participation factors, switchable capacitors and transformer tap adjustment are handled by the Continuation Power Flow. The contingency list contains fourteen contingencies related to the seven tie lines between Area 1 and Area 2. The faults are 3-phase balanced faults occurring at both end buses of the transmission line.

The P-V curve traced by Continuation Power Flow along the direction of power transfers between Area 1 and Area 2 reaches the corresponding nose point at which the real interface-flow is 3263 MW. While this nose point is often referred to as the maximum power transfer point or maximum loading point, it is evident that this maximum power transfer point is not a feasible operating point from the static viewpoints of voltage-limit, thermal-limit or the dynamic viewpoint of transient stability. In other words, the maximum power transfer point usually does not represent the static PTC or the dynamic PTC.

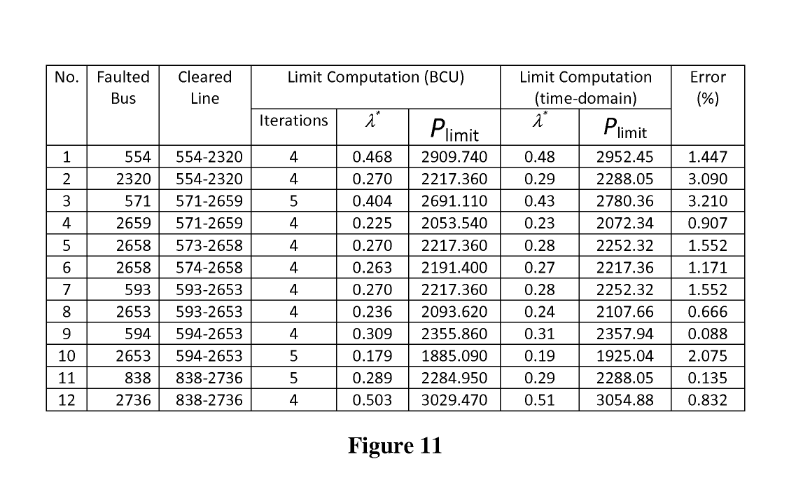

FIG. 11 shows the accuracy of BCU-limiter, as compared with the time-domain approach on twelve contingencies in terms of error. The errors are all between 0% and 3.2%. It shows the accuracy and conservativeness nature of the invented BCU-limiter.

### Real-Time Dynamic PTC in 2-Dimensional Nomogram

A dynamic PTC nomogram is a two-dimensional display of dynamic PTC in terms of two interface flows. Nomograms provide vital information for power system operators to operate power systems within power transmission dynamic security limits and with a ‘comfort zone’.

A nomogram always involves two interface paths. In computing a nomogram, we first need to associate one interface path with the X axis and the other interface path with the Y axis. Then we separate all source generators involved in the stress pattern into two groups. The source group that is responsible for the flow change in the X axis path is classified as group X, which is denoted as G₁. The source group that is responsible for the power flow change in the Y axis path is classified as group Y, which is denoted as G₂.

We compute the dynamic PTC nomogram in the following way. We at first create two independent base generation vectors b_{g1}, b_{g2} for G₁ and G₂ respectively. Then, we create two independent coefficients for a₁, a₂ respectively. The overall generation vector considering both source groups will be the same as equation (6). By assigning at, a₁, a₂ different values, we can create a family of generation/load stress patterns, which spans the entire feasible generation/load stress space.

For each generation/load stress pattern, we will use the invented TEPCO-BCU-Limiter to compute the dynamic PTC (i.e. the boundary of the nomogram along the stress pattern). The invented solution algorithm to compute the dynamic PTC nomogram is as follows:
Step 1: Separate source generators into two groups G₁ and G₂, and assign a₁=0 and a₂=1
Step 2: Compute b_{g} using the equation:

b_{g}=a₁b_{g1}+a_{g}b_{g2} (6)
Step 3: Use the invented method to compute the (one-dimensional) system-wide dynamic PTC and the corresponding interface dynamic PTC's along the direction b_{g}.
Step 4: Assign different values for a₁ and a₂ in the equation of Step 2, and repeat Step 2: Compute b_{g} using the equation:

b_{g}=a₁b_{g1}+a₂b_{g2} (6)
to Step 3 to compute all points on the nomogram boundary (i.e. curve).
Step 5: Export the dynamic PTC nomogram curve and the corresponding limiting contingency of each computed point on the nomogram boundary.

It is sometimes useful to represent the dynamic PTC nomogram in terms of pre-contingency interface power flow (i.e. the base-case interface power flow) at the limit point. The system-wide dynamic PTC nomogram is then mapped into each interface dynamic PTC nomogram.

### Real-Time Dynamic ATC

The real-time ATC is the difference between the real-time PTC and the current (i.e. real-time) power flow. To provide a real-time dynamic ATC (i.e. ATC subject to transient stability constraints), it is necessary to have some real-time information regarding a system's operating conditions.

This invention proposes to apply wide-area measurement system (WAMS) such as phasor measurement units (PMUs) installed at selected tie-lines and buses to obtain required real-time real power and reactive power information. The task of determining real-time dynamic ATC subject to dynamic security constraints is very challenging due to the nonlinear nature of interconnected power systems and the tremendous computation requirements of the transient stability analysis of credible contingencies.

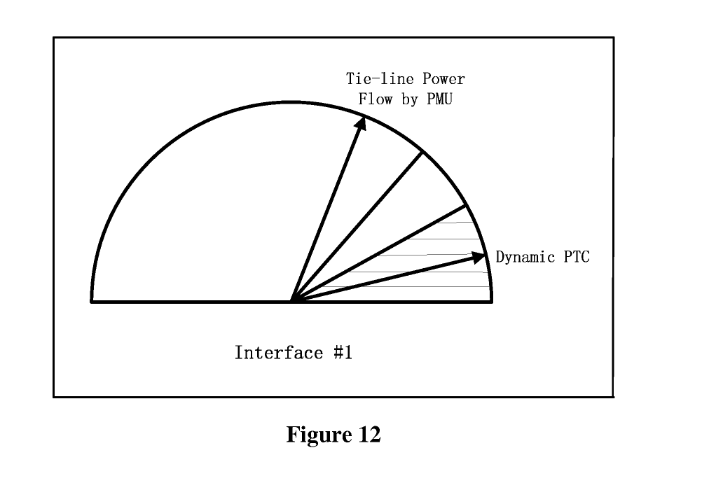

FIG. 12 shows tie-line power flow of interface #1 is measured by PMU's placed across interface #1 while the dynamic PTC of interface #1 is computed by the invented method for computing the real-time dynamic PTC. The difference between the real-time dynamic PTC and the real-time tie-line power flow is the real-time dynamic ATC.

Given an operating point (derived from a state estimator), a network topology, a set of pre-determined interfaces and a contingency list associated with each interface, we develop a PMU-assisted, real-time dynamic ATC determination system. There are four key components in the invented PMU-assisted, real-time dynamic ATC determination system:
(1) stator estimator and network topology analyzer from an energy management system, which provides the current operating point,
(2) the invented real-time dynamic power transfer capability system, which provides the dynamic PTC,
(3) the real-time measurement units such as PMUs, placed various locations including a set of pre-determined interfaces, and
(4) the real-time ATC display system with both one-dimensional and two-dimensional ATC monitoring system.

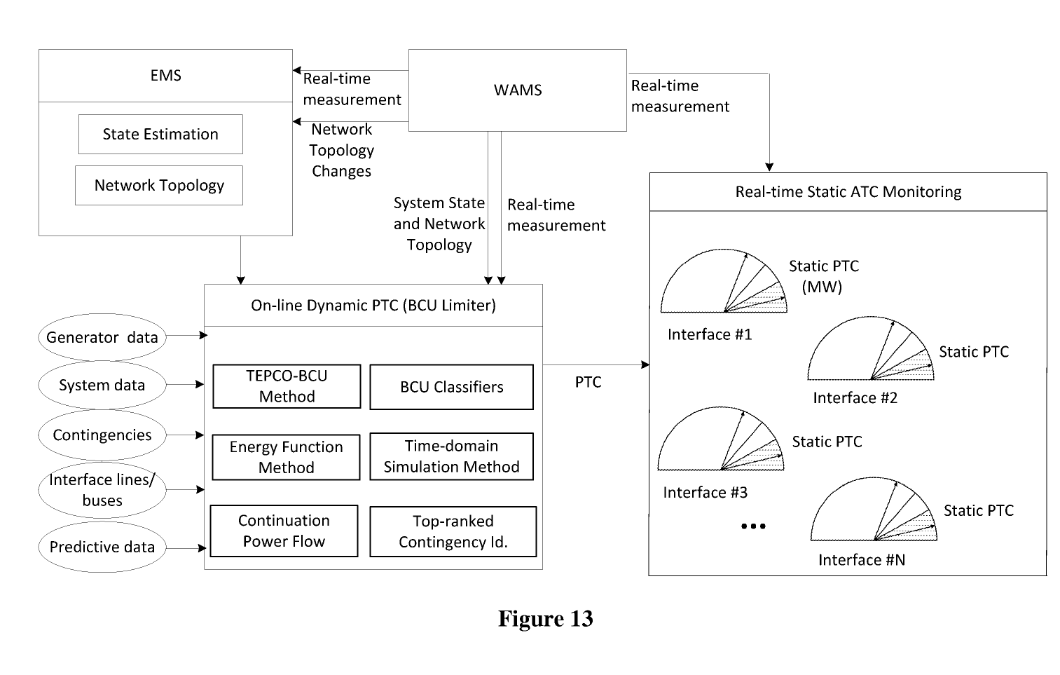

The output of the PMU-assisted, real-time dynamic ATC determination system can be expressed as the one-dimensional dynamic PTC (see FIG. 12). The proposed architecture of the Real-time dynamic ATC determination system in One-dimensional maps is shown FIG. 13. In this architecture, the core computation engines for real-time dynamic PTC determination are composed of TEPCO-BCU methods, BCU classifiers, energy function method, continuation power flow method, time-domain simulation method and top-ranked contingency identification method.

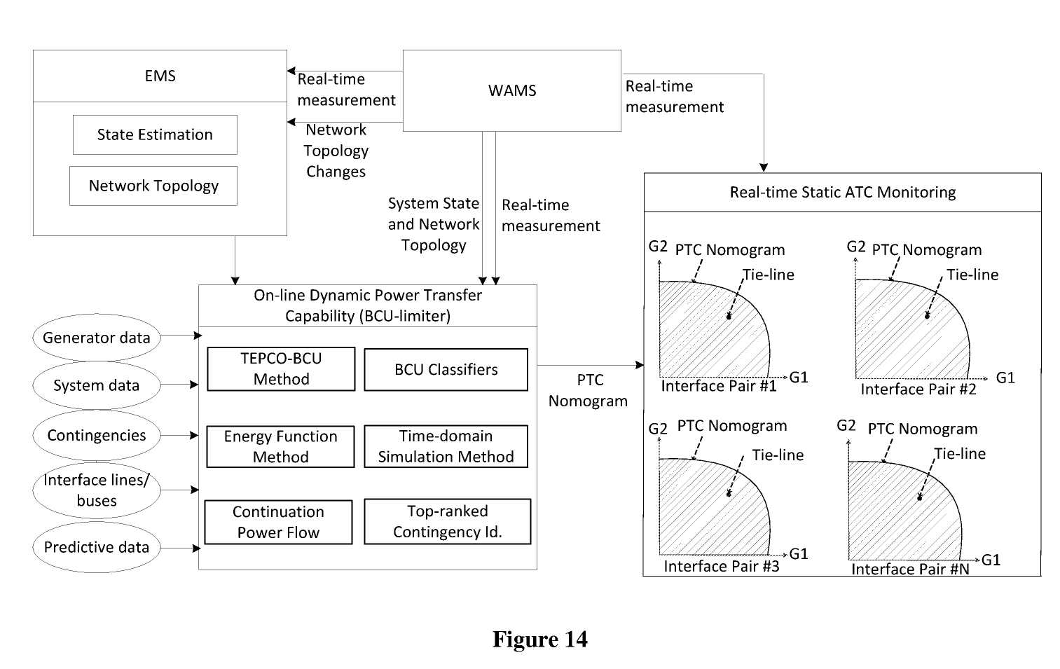

The proposed architecture of the Real-time dynamic ATC nomogram (i.e. in Two-dimensional maps) is shown in FIG. 14.

It should be pointed out that the solution methods of the invented system can also determine the top-ranked interface dynamic power transfer limit of each selected interface under the contingency list associated with each interface.

This real-time dynamic ATC determination system has the following features:
(1) The real-time dynamic ATC calculation methodology determines the top-ranked system-wide power transfer limits subject to dynamic security constraints of a contingency list.
(2) The system identifies, for each top-ranked power transfer limit, the corresponding limiting contingency and the corresponding binding constraint.
(3) The system maps each top-ranked system-wide power transfer limit into the power transfer limit of each selected tie-line interface under the contingency.
(4) The real-time measurement of power flow across each selected tie-line interface is obtained from the installed PMUs. For each limiting contingency, the difference between the corresponding power transfer limit and the current power transfer is the real-time available transfer capability of the system associated with the top limiting contingency and the corresponding binding constraint expressed as the power flow across each interface.

### Real-Time Static and Dynamic PTC

We now describe the invented real-time methodology to compute real-time PTC subject to static and dynamic security constraints, which is described as follows:
Step 1: Apply the Continuation Power Flow (CPFLOW) method to compute the P-V curves for the base-case power system for a proposed power transaction.
Step 2: Compute the static PTC subject to static constraints of a credible contingency list; termed as static PTC. The corresponding operating point is termed as the (base-case) static-security-constrained (SSC) operating limit point. Record the corresponding limiting contingency.
Step 3: Apply the TEPCO-BCU engine to the current base-case operating point, which is obtained from the state estimation, to perform transient stability analysis of the operating point subject to a contingency list.
Step 4: If there is an insecure or critical contingency at the (current) base-case operating point, then the dynamic PTC is zero for the proposed power transaction—output the real-time static and dynamic PTC to be zero and stop the computation. Otherwise, set the base-case operating point as the lower bound of the dynamic PTC and record the corresponding critical contingencies and their corresponding energy margin and continue to the next step.
Step 5: Apply the TEPCO-BCU engine to the base-case static-security-constrained (SSC) operating limit point to perform transient stability analysis subject to the contingency list.
Step 6: If there is no insecure or critical contingency at the base-case SSC operating limit point, then the dynamic PTC is greater than the static PTC for the proposed power transaction, and go to Step 10. Otherwise, set the base-case SSC operating limit point as the upper bound of the dynamic PTC, record the corresponding insecure and critical contingencies and their corresponding energy margin, and continue to the next step.
Step 7: Select a loading condition on the P-V curve between the lower bound and the upper bound of the dynamic PTCs based on an energy-margin one-dimensional search method such as the golden bisection search algorithm.
Step 8: Apply the TEPCO-BCU method to the selected loading condition of Step 6 to perform transient stability analysis subject to the newly-updated contingency list (such as a selected set of contingencies based on the insecure and critical contingencies at both the upper bound operating point and lower bound operating point).
Step 9: If one or more insecure contingencies are detected, set the current loading condition as the upper bound of the dynamic PTC; otherwise, update the lower bound of dynamic PTC by the currently selected loading condition. If the difference between the lower bound and upper bound of the dynamic PTC is larger than a specified number, then go to Step 6.
Step 10: Export the top-limiting contingencies and the corresponding static and dynamic PTCs and stop.

The static and dynamic PTC load margin can be expressed in several ways. It is sometimes useful to represent the static and dynamic PTC load margin in terms of pre-contingency interface power flow (i.e. the base-case interface power flow) at the limit point. The system-wide static and dynamic PTC load margin is then mapped into each interface static and dynamic PTC load margin.

### Real-Time Static and Dynamic PTC in 2-Dimensional Nomogram

We compute the static and dynamic PTC nomogram in the following way. We at first create two independent base generation vectors) b_{g1}, b_{g2} for G₁ and G₂ respectively. Then, we create two independent coefficients for a₁, a₂ respectively. The overall generation vector considering both source groups will be the same as equation (6), below. By assigning a₁, a₂ different values, we can create a family of generation/load stress patterns, which spans the entire feasible generation/load stress space.

For each generation/load stress pattern, we will use the invented TEPCO-BCU-Limiter to compute the static and dynamic PTC nomogram (i.e. the boundary of the nomogram along the stress pattern). We continue this procedure for a family of generation/load stress patterns to obtain the static and dynamic PTC nomogram. The invented solution algorithm to compute the static and dynamic PTC nomogram is as follows
Step 1: Separate source generators into two groups G₁ and G₂, and assign a₁=0 and a₂=1
Step 2: Compute b_{g} using the equation:

b_{g}=a₁b_{g1}+a₂b_{g2} (6)
Step 3: Use the proposed real-time PTC method to compute the (one-dimensional) system-wide static and dynamic PTC and the corresponding interface static and dynamic PTC's along the direction b_{g}.
Step 4: Assign different values for a₁ and a₂ in the equation of step 2 and repeat Step 2: Compute b_{g} using the equation:

b_{g}=a₁b_{g1}+a₂b_{g2} (6)
to Step 3 to compute all points on the nomogram boundary (i.e. curve).
Step 5: Export the static and dynamic PTC nomogram curve and the corresponding limiting contingency of each computed point on the nomogram boundary.

The static and dynamic PTC nomogram can be expressed in several ways. It is sometimes useful to represent the static and dynamic PTC nomogram in terms of pre-contingency interface power flow (i.e. the base-case interface power flow) at the limit point. The system-wide static and dynamic PTC nomogram is then mapped into each interface static and dynamic PTC nomogram.

### Real-Time Static and Dynamic ATC

The task of determining real-time static and dynamic ATC is very challenging due to the nonlinear nature of interconnected power systems and the tremendous computation requirements of the line thermal limits, bus voltage limits, voltage stability constraints and transient stability constraints of credible contingencies. Given an operating point (derived from a state estimator), a network topology, a set of pre-determined interfaces and a contingency list associated with each interface, we develop a PMU-assisted, real-time static and dynamic ATC determination system.

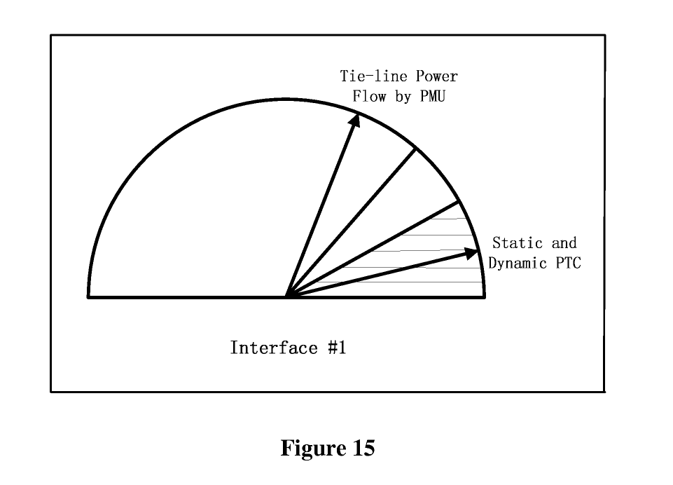

FIG. 15 shows tie-line power flow of interface #1 is measured by PMU's placed across interface #1 while the static and dynamic PTC of interface #1 is computed by the invented method. The difference between the real-time static and dynamic PTC and the real-time tie-line power flow is the real-time static and dynamic ATC.

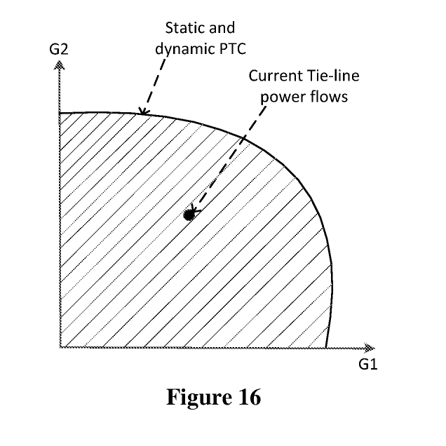

FIG. 16 shows how the output of the PMU-assisted, real-time static and dynamic ATC determination system can be expressed as a two-dimensional nomogram.

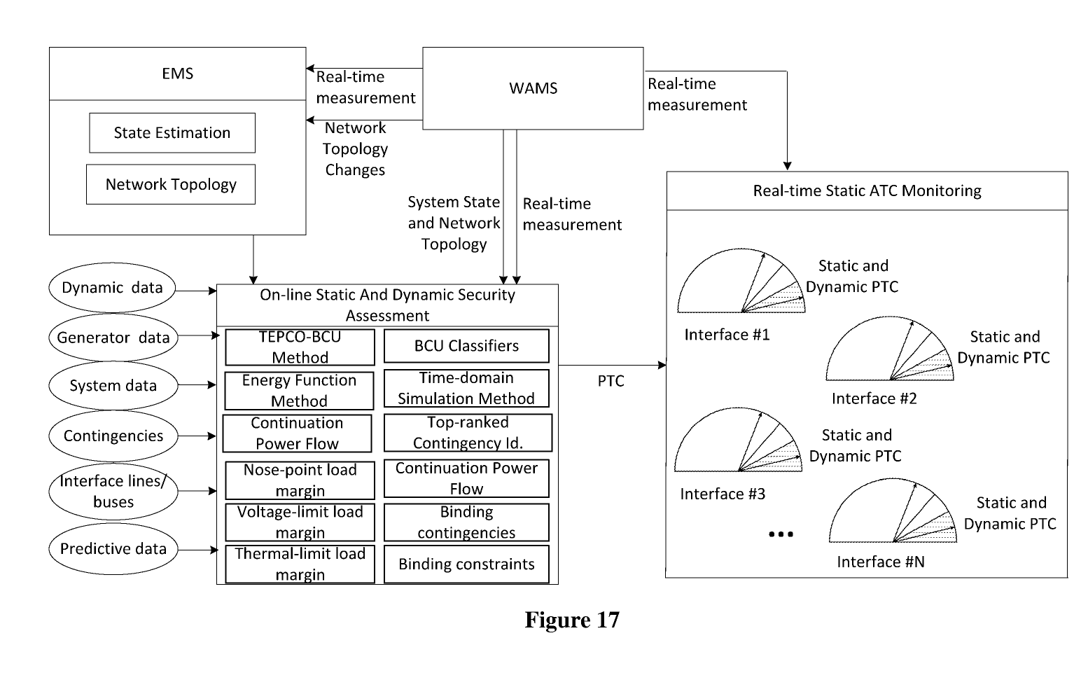

FIG. 17 shows an architecture of a PMU-assisted, real-time static and dynamic available transfer capability determination system with one-dimensional meter displays for each interface.

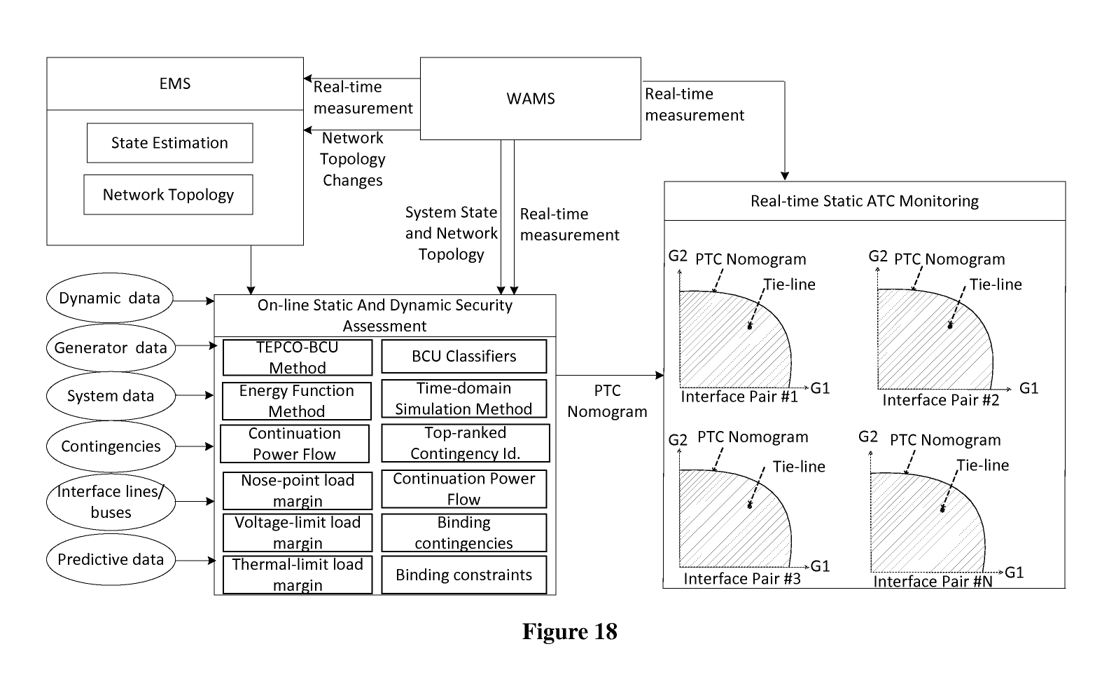

FIG. 18 shows an architecture of a PMU-assisted, real-time static and dynamic available transfer capability determination system with two-dimensional monogram displays for each pair interfaces.

The output of the PMU-assisted, real-time static and dynamic ATC determination system can be expressed as an one-dimensional meter (see FIG. 15). The output of the PMU-assisted, real-time static and dynamic ATC determination system can be expressed as a two-dimensional nomogram (see FIG. 16). The proposed architecture of the Real-time dynamic ATC determination system in One-dimensional maps is shown in FIG. 17. In this architecture, the core computation engines for real-time static and dynamic PTC determination are composed of TEPCO-BCU methods, BCU classifiers, energy function method, continuation power flow method, time-domain simulation method, top-ranked contingency identification method, nose-point load margin estimation, voltage-limit load margin estimation, thermal-limit load margin estimation. The proposed architecture of the Real-time dynamic ATC nomogram (i.e. in Two-dimensional maps) is shown in FIG. 18.

There are four key components in the invented PMU-assisted, real-time static and dynamic ATC determination system:
(1) stator estimator and network topology analyzer from an energy management system;
(2) the invented real-time static and dynamic power transfer capability system;
(3) the real-time measurement units such as PMUs, placed various locations including a set of pre-determined interfaces; and
(4) the real-time ATC display system with both one-dimensional and two-dimensional ATC monitoring system.

It should be pointed out that the solution methods of the invented system can also determine the top-ranked interface static and dynamic power transfer limit of each selected interface under the contingency list associated with each interface.

This real-time dynamic ATC determination system has the following features:
(1) The real-time static and dynamic security ATC calculation methodology determines the top-ranked system-wide power transfer limits subject to both static and dynamic security constraints of a contingency list.
(2) The system identifies, for each top-ranked power transfer limit, the corresponding limiting contingency and the corresponding binding constraint.
(3) The system maps each top-ranked system-wide power transfer limit into the power transfer limit of each selected tie-line interface under the contingency.
(4) The real-time measurement of power flow across each selected tie-line interface is obtained from the installed PMUs. For each limiting contingency, the difference between the corresponding power transfer limit and the current power transfer is the real-time available transfer capability of the system associated with the top limiting contingency and the corresponding binding constraint expressed as the power flow across each interface.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method of evaluating a static power transfer capability (PTC) of an interconnected power system with respect to a power transfer transaction subject to security constraints comprising the steps of:
a) initializing the evaluation by building a power transfer vector to represent the proposed power transfer transaction and forming parameterized power flow equations by incorporating the power transfer vector into base-case power flow equations;
b) ranking a plurality of contingencies with respect to static security violation criteria to determine any associated violated constraints;
c) computing a first-contingency PTC, and identifying at least one corresponding binding contingency;
d) ranking a plurality of contingency-constrained PTCs and first contingency incremental transfer capabilities (FCITCs) giving a PTC for the interconnected power system with respect to a power transfer transaction; and
e) outputting the PTC and an FCITC for the power system with the power transaction under each binding contingency and the associated violated constraints.

2. The method of claim 1, in which the initializing step (a) comprises the steps of:
(i) building a the power transfer vector b to mathematically represent the power transfer transaction;
(ii) forming parameterized power flow equations by incorporating the power transfer vector b into base-case power flow equations f(x)−λb=0; and
(iii) initializing a generation/load condition number λ by setting λ=λ₀ to the base case.

3. The method of claim 2, in which the ranking step (b) comprises the steps of:
(i) using a look-ahead scheme to rank the set of contingencies L in terms of branch MVA violation into a ranked set of contingencies L(mva);
(ii) using a look-ahead scheme to rank the set of contingencies L in terms of bus voltage violation into a ranked set of contingencies L(volt); and
(iii) using a look-ahead scheme to rank the set of contingencies L in terms of load margin into a ranked set of contingencies L(margin).

4. The method of claim 3, in which the computing step (c) comprises the steps of:
(i) selecting the top Nₐ contingencies from the ordered set L(mva), the top N_{b} contingencies from the ordered set L(volt), and the top N_{c} contingencies from the ordered set L(margin);
(ii) renumbering the contingencies from step (c)(i) into l₁, l₂ . . . , l_{N}_{ₐ}_{+N}_{_{b}}_{+N}_{_{c}};
(iii) if there are any sets of duplicate contingencies, eliminating all but one contingency from each set of duplicate contingencies;
(iv) defining a new set L_{static} ▴{I [symbol] ₀, I [symbol] ₁, . . . , I [symbol] _{N}_{ₜₒₜₐₗ}}, where I [symbol] ₀ represents the base case power system;
(v) for each contingency in L_{static}, perform the following steps:
(A) setting j=0
(B) using CPFLOW to compute solutions of parameterized power flow equations under contingency [symbol] lᵢ for each generation/load condition number λⱼ=λⱼ+Δλⱼ, where Δλⱼ=0 if j=0; otherwise Δλⱼ is determined by the step-size control in CPFLOW;
(C) if the post-contingency power flow solution [X( [symbol] ᵥ [symbol] ,λ]ₗ) satisfies the following static security constraints
voltage: V^{m} [symbol] ≦V(lᵥλⱼ)≦V^{M}
line current: I^{m}≦I(lᵥλⱼ)≦I^{M}
facility loading: g(lᵥλⱼ)≦0
then set j=j+1 and repeat from step (v)(B);
otherwise, set Cbind=the corresponding violated constraints and continue to step (v)(D);
(D) if |λⱼ−λⱼ₋₁|< [symbol] , continue from step (v)(E), otherwise, set
$$\text{?} = \frac{\text{?}}{2} \\ \text{?} \text{indicates text missing or illegible when filed} \qquad$$
and use CPFLOW to compute the solutions of the parameterized power flow equations under contingency [symbol] lᵢ for the generation/load condition number λᵢ= λ̅ⱼ̅;
(I) if the post-contingency power flow solution X(l_{g} λ̅ⱼ) satisfies the static security constraints, then set λⱼ₋₁= λ̅ⱼ̅ and repeat this step (v)(D);
otherwise set λⱼ= λ̅ⱼ̅, and Cbind=the corresponding violated constraints and repeat this step (v)(D);
(E) recording the contingency [symbol] Iⱼ, the generation/load condition number λ̅ⱼ̅=λⱼ₋₁, and the corresponding violated constraints CVⱼ, giving the first-contingency available transfer capability under contingency [symbol] lⱼ as λ̅ⱼ̅ λ₀ with the binding constraint CVⱼ;
(F) if t<Nₜₒₜₐₗ, set i=i+1 and go to step (v)(1); otherwise, go to step (d).

5. The method of claim 4, in which the step (d) of ranking comprises the steps of:
(i) ranking the set L_{static} according to each value λ̅ⱼ̅ obtained in step (c)(v)(E), such that:
the ranked contingency set is L̅_{static}={l₁, l₂, . . . lₜₒₜₐₗ} such that λ̅₁̅≧ λ̅₂̅≧ . . . ≧ λ̅ₜₒₜₐₗ,
the first-contingency PTC or FCITC subject to static voltage stability constraints and static security constraints of the contingency set L is
λₜₒₜₐₗ=( λ̅ₜₒₜₐₗ−λ₀), the binding contingency lₜₒₜₐₗ;
the associated violated constraint is CVₜₒₜₐₗ; and
the PTC under contingency Iⱼ, is λⱼ=( λ̅ⱼ̅−λ₀) with the binding constraint CVⱼ, for j=1, 2, . . . , total−1_{□}.

6. The method of claim 1, in which in step (e), PTC is expressed in terms of amount of PTC between sending areas and receiving areas.

7. The method of claim 1, in which in step (e), PTC is represented in terms of base-case interface power flows of a transmission interface.

8. The method of claim 1, in which in step (e), PTC is displayed as a two-dimensional nomogram in terms of two interface flows.

9. The method of claim 8, in which the nomogram is created by the steps of:
(a) separating source generators into two groups G₁ and G₂, and assign a₁=0 and a₂=1;
(b) computing b_{g}=a₁b_{g1}+a₂b_{g2};
(c) computing a one-dimensional system-wide static PTC and corresponding interface static PTC's along the direction b_{g};
(d) assigning different values for a and a 7 in the equation of step (b) and repeat the method from step (b) to compute all points on the nomogram curve;
(e) exporting the static PTC nomogram curve and the corresponding limiting contingency of each computed point on the nomogram boundary.

10. The method of claim 1, further comprising the step of computing a difference between the PTC and a current actual power flow, giving a real-time available transfer capacity (ATC).

11. An energy-margin-based search method to select a next operating point between two known operating points on a P-V curve, comprising the steps of:
(a) using a BCU method to compute an energy margin of contingency i at a base-case λ=λ₀ [symbol] , such that the energy margin of contingency i is Wᵢ [symbol] ^{(λ}^{₀}⁾;
(b) if Wᵢ [symbol] ^{(λ}^{₀}⁾>0, designating contingency i as stable;
(c) using the BCU method to compute the energy margin of contingency i at another loading condition, λ=λᵢ, such that the energy margin of contingency i is Wᵢ [symbol] ^{(λ}^{₁}⁾;
(d) if Wᵢ [symbol] ^{(λ}^{₁} [symbol] ⁾<0, designating contingency i as unstable at the loading condition λ=λ₁, such that the power transfer limit (PTL) relative to contingency i lies between the two loading conditions λ₀λ₁;
(e) using a one-dimensional search method, identify the PTL subject to contingency i;
(f) computing a new loading condition
$${λ}_{2} = \frac{{λ}_{0} + {λ}_{1}}{2} ;$$
(g) computing the energy margin at the new loading condition Wᵢ(λ₂);
(h) computing the next loading level
$$\text{?} = \text{?} + \frac{\text{?}}{\sqrt{\text{?} - {W}_{□} ( {λ}_{0} ) {W}_{□} ( {λ}_{1} )}} ; \\ \text{?} \text{indicates text missing or illegible when filed} \qquad$$
and
(i) repeating the method for the next loading condition to be evaluated for transfer stability assessment λ_{□}=λ [symbol] .

12. The method of claim 11, wherein the one-dimensional search method of step (e) is a bracketing algorithm, a bisection algorithm, a secant algorithm or Ridder's algorithm.

13. A method of evaluating a dynamic power transfer capability (PTC) of an interconnected power system comprising the steps of:
(a) applying the CPFLOW method to compute a P-V curve for a base-case power system for a proposed power transaction;
(b) applying the TEPCO-BCU method to the base-case operating point to perform transient stability analysis of the operating point subject to a contingency list;
(c) if there is an insecure or critical contingency at the current base-case operating point, then stop the method;
(d) setting the base-case operating point as the lower bound of the dynamic PTC and record the corresponding critical contingencies and their corresponding energy margin;
(e) applying the TEPCO-BCU method to a base-case nose point to perform a transient stability analysis subject to the entire contingency list;
(f) if there is no insecure or critical contingency at the base-case nose point, then output the dynamic PTC as the same value of static PTC and stop;
(g) setting the base-case nose point as the upper bound of the dynamic PTC;
(h) recording the corresponding insecure and critical contingencies and their corresponding energy margin;
(i) selecting a loading condition on the P-V curve between a lower bound and an upper bound of the dynamic PTCs based on an energy-margin one-dimensional search method;
(j) applying the TEPCO-BCU method to the selected loading condition from step (i) to perform transient stability analysis subject to the newly-updated contingency list;
(k) if at least one insecure contingency is detected, set the current loading condition as the upper bound of the dynamic PTC; otherwise, update the lower bound of dynamic PTC by the currently selected loading condition; and
(l) if a difference between the lower bound and upper bound of the dynamic PTC is larger than a selected number, then repeat the method from step (i):
(m) exporting the top-limiting contingencies and compute the corresponding dynamic PTCs.

14. The method of claim 13, wherein the one-dimensional search method of step (i) is a bracketing algorithm, a bisection algorithm, a secant algorithm or Ridder's algorithm.

15. The method of claim 13, wherein the one-dimensional search method of step (i) is a golden bisection algorithm.

16. A method of creating a dynamic PTC nomogram graph in terms of two interface flows, in which a first interface path is associated with the X axis and a second interface path is associated with the Y axis, a group of source generators responsible for a flow change in the X axis path is denoted as G₁, and a group of source generators responsible for a power flow change in the Y axis path is denoted as G₂, the method comprising the steps of:
(a) assigning a₁=0 and a₂=1;
(b) computing b_{g} using the equation b_{g}=a₁b_{g1}+a₂b_{g2};
(c) computing the one-dimensional system-wide dynamic PTC and the corresponding interface dynamic PTC's along the directions b_{g};
(d) assigning different values for a₁ and a₂ in the equation of step (b), and repeat from step (b) to compute all points on the nomogram curve: and
(e) exporting the dynamic PTC nomogram curve and the corresponding limiting contingency of each computed point on the nomogram boundary.

17. A method of computing a power transmission capability (PTC) subject to static and dynamic security constraints, comprising the steps of:
(a) applying the CPFLOW method to compute the P-V curves for the base-case power system for a proposed power transaction;
(b) computing the static PTC subject to static constraints of a credible contingency list;
(c) determining a corresponding operating point termed as the base-case static-security-constrained (SSC) operating limit point;
(d) recording a corresponding limiting contingency for the SSC;
(e) applying the TEPCO-BCU method to a current base-case operating point, obtained from a state estimation, to perform transient stability analysis of the operating point subject to a contingency list;
(f) if there is an insecure or critical contingency at the current base-case operating point, output the real-time static and dynamic PTC as zero and stop the method;
(g) setting the base-case operating point as the lower bound of the dynamic PTC and record the corresponding critical contingencies and their corresponding energy margin;
(h) applying the TEPCO-BCU method to the base-case static-security-constrained (SSC) operating limit point to perform transient stability analysis subject to the contingency list;
(i) if there is no insecure or critical contingency at the base-case SSC operating limit point, then continue the method at exporting step (p);
(j) setting the base-case SSC operating limit point as the upper bound of the dynamic PTC;
(k) recording the corresponding insecure and critical contingencies and their corresponding energy margin;
(l) selecting a loading condition on the P-V curve between the lower bound and the upper bound of the dynamic PTCs based on an energy-margin one-dimensional search method;
(m) applying the TEPCO-BCU method to the selected loading condition of step (k) to perform transient stability analysis subject to the newly-updated contingency list;
(n) if at least one insecure contingency is detected, set the current loading condition as the upper bound of the dynamic PTC; otherwise, update the lower bound of dynamic PTC by the currently selected loading condition;
(o) if a difference between the lower bound and upper bound of the dynamic PTC is larger than a specified number, then continue the method at step (i);
(p) exporting the top-limiting contingencies and the corresponding static and dynamic PTCs.

18. The method of claim 17, wherein the one-dimensional search method of step (l) is a bracketing algorithm, a bisection algorithm, a secant algorithm or Ridder's algorithm.

19. The method of claim 17, wherein the one-dimensional search method of step (l) is a golden bisection algorithm.

20. The method of claim 17, further comprising the step of computing a difference between the PTC and a current actual power flow, giving a real-time static and dynamic available transfer capacity (ATC).
